(19) United States
(12) Patent Application Publication
(10) Pub. No.: US 2005/0145366 A1
(43) Pub. Date: Jul. 7, 2005

(54) Heat-sink with large fins-to-air contact area

(76) Inventor: David Erel, Ramat HaSharon (IL)

Correspondence Address: Shiboleth Yisraell Roberts Zisman & Co, 350 Fifth Avenue, 60th Floor, New York, NY, 10118, US

(21) Appl. No.: 10/502,295

(22) PCT Filed:
(86) PCT No.: PCT/IL03/00066

Related U.S. Application Data
(60) Provisional application No. 60/352,252, filed on Jan. 30, 2002.
(60) Provisional application No. 60/374,798, filed on Apr. 24, 2002.
(60) Provisional application No. 60/394,513, filed on Jul. 10, 2002.

(51) Int. Cl. H05K 7/20

(52) U.S. Cl. 165/80.3

(57) ABSTRACT

A heat sink adapted for cooling a heat generating component, operative with an air moving means to generate airflow and remove the generated heat. The heat sink comprises a heat conducting element in thermal contact with the heat generating component, which is also in thermal contact with a plurality of fins having through fin-perforations defining free airflow passages and heat paths so as to spread the generated heat through the perforated fins. The structural configuration and relative spatial disposition of the perforated fins form airflow directing elements for the generated airflow, which flows via an air inlet and through inflow and outflow air passages which are in fluid communication via the fin-perforations, such that the airflow directing elements at least partially block the generated airflow, thus substantially directing all of it to flow via each of the fin-perforations, thereby developing cross-flow only once through the fin-perforations so as to exit via the air outlet.

### FIELD OF THE INVENTION

The present invention generally relates to cooling devices for cooling electrical components, and more particularly, to a low-profile heat-sink with large fins-to-air contact area and a fan element, suitable for forced airflow, active cooling of electronic components disposed on densely packed printed circuit boards.

### BACKGROUND OF THE INVENTION

The present invention is a continuation of prior, US Provisional Patent Applications: 60/352 252, dated Jan. 30, 2002; 60/374 798, dated Feb. 24, 2002; and 60/394 513 dated Oct. 7, 2002 filed by the named sole inventor, David Erel, and which assume the protection of the respective dates of filing for the inventive concepts and preferred embodiments described in their respective prior Provisional Patent Applications and which are reintroduced hereinbelow.

Electronic cabinets, such as used in the computer industry, commonly comprise a plurality of double-sided, printed circuit boards (PCBs) supporting densely packed structures, hereinafter referred to as components. The PCBs are disposed parallel to one another with minimal spacing between each other and between the PCBs and the nearest walls of the cabinet so as to reduce the cabinet's overall dimensions. The minimal spacing is determined mainly in accordance with the requirements for optimal heat dissipation which is accomplished either by natural convection or, more commonly, by forced airflow.

Another on-going trend is the increase in dissipated heat from components due to their reduction in size and the concurrent increase in density of the basic elements comprising the components, such as transistors and diodes, coupled with an increase in the operating frequency of such densely packed electronic units.

A common procedure to increase the heat dissipation capacity from a component to the air is by utilizing a finned cooling device, with its base thermally attached to the heat-generating component. The increased fins-to-air heat transfer surface area enhances the heat dissipation either by natural air convection and radiation or by forced air flowing over the fins of the cooling device. A sufficient distance between adjacent PCBs must therefore be provided to allow for the combined height of the cooling device and the heat-generating component.

Modern, high-power components, such as microprocessors, cannot economically be cooled by a cooling device that utilizes the circulated forced air which cools the cabinet if the power of the fan and the generated noise is to be maintained at reasonable levels. Therefore, a dedicated fan is utilized in association with the cooling device to cool high-power heat-generating components. With the cooling device and the fan mounted on a heat-generating component, most commonly one on top of the other, their combined height dictates the minimal distance between the PCBs and the cabinet.

It is yet another goal of micro-processor manufacturers to lower the center of gravity of the cooling device and minimize the moments transferred from the cooling device to the PCB directly or through the processor's socket when the cooling device becomes subjected to excessive inertial forces, such as created when the enclosure containing the cooling device is mishandled during transportation. This can lead to the cooling device inadvertently causing damage to the PCB and the processor.

Reference is made herein to prior art patents U.S. Pat. Nos. 5,785,116 to Wagner; 5,583,746 to Wang; and 5,309,983 to Bailey which address the problem of reducing the overall height of a cooling device disposed above the components mounted on a PCB.

These patents suggest a cooling device wherein a fan is centrally embedded, surrounded by heat-dissipating fins. Cooling air flows horizontally between the fins, either in a single or a double path. However, the pressure, which such an embedded fan is able to develop, is limited due to the small diameter of the blades. In order to overcome this limitation, the rotating speed of the fan is increased to increase the pressure and cooling capacity of the fan, but this brings about an undesirable increase in noise.

### SUMMARY OF THE INVENTION

Accordingly, it is a principal object of the present invention to overcome the above disadvantages and drawbacks of the prior art by providing a cooling device with high cooling capacity and minimal axial thickness that is suitable for cooling heat-generating components mounted on densely packed PCBs in a manner that enables minimizing the distance between adjacent PCB's.

In the preferred embodiment of the invention, a cooling device has a fan element, wherein the blades of the fan are disposed outside the area occupied by the fins, with the footprint of the fan blades symmetrically and externally surrounding the area occupied by the fins at a specific radial distance, enabling provision of higher pressure for the same fins-to-air contact area, without excessively increasing the rotating speed of the fan and the associated noise of rotation.

Therefore there is provided a cooling device for dissipating heat to the surrounding air from at least one heat-generating component, the cooling device comprising:
at least one heat-sink having a pre-defined surface area, and having a plurality of heat-conducting elements arranged in a low-profile configuration, each of the elements provided with a plurality of air passages and having large surface-to-air contact area with the surrounding air, the large contact area being defined by a ratio between air-passage-areas formed in the elements and the pre-defined surface area;
wherein the elements are in thermal contact with the at least one heat-generating component so as to facilitate thermal flow from the at least one heat-generating component to the elements and to the surrounding air; and
wherein the heat sink is adapted to operate with air-moving means to provide minimal thermal-flow resistance from the elements in thermal contact with the at least one heat-generating component to the air, per specific volume occupied by the cooling device.

In another embodiment of the invention, strip fins are provided which are selected from the group of tightly wound, folded, and stacked strip fins and characterized by a plurality of protrusions.

In yet another embodiment of the invention, stacked perforated plate fins are utilized with the thermal flow of the dissipated heat directed through the fins while the air flows generally axially vertically to the thermal flow in a manner that enables a substantial increase in the contact area between the fins and the air without an increase in the volume of the given cooling device.

It should be appreciated that the large fins-to-air contact area and the externally rotating blades enable the advantageous manufacturing of low-profile cooling devices with high heat-dissipating capacity per specific volume over that generally found in the prior art.

In still another embodiment of the invention, the low-profile, high density fins of the cooling device are combined with a low-profile centrifugal blower whose motor is wholly disposed within a plenum, such as a through-bore or a blind bore, provided in the center of the cooling device. The blades in this embodiment rotate outside the supporting area of the fins, with the impeller rotating proximally to the fins. Thus, only the axial thickness of the free section of the impeller blades is added to the axial dimension of the cooling device, defining the overall axial dimension of the cooling device, which further dictates the minimal spacing between the adjacent PCBs. The large rotating radius of the blades provides the higher pressure necessary to overcome the pressure losses created by the airflow over the high-density fins.

In still another embodiment of the present invention, an axial fan is utilized, with its motor embedded within a through-bore, while the low-profile axial blades of the fan rotate above the cooling device so that the footprint of the blades overlaps that of the footprint of the fins. The axial blades are adapted to enable air suction from the space between the fins. Alternatively, by turning the blades on their rotating shaft in an upside down position, the blades push air into the space between the fins.

In a further embodiment of the present invention, a low profile axial fan is utilized, with its motor disposed above the fins, while the blades of the fan rotate above the cooling device so that the footprint of the blades overlaps that of the footprint of the supporting area of the fan itself. As described above, the axial blades are adapted to enable air suction from the space between the fins or to push air into the space between the fins.

In yet another embodiment of the present invention, at least one centrifugal blower is mounted on at least one axial side of the heat-sink. The high pressure provided by the blower enables the utilization of an air filter mounted on the air inlet to the fins for additional cooling.

All embodiments of the present invention mentioned hereinbefore refer to a cooling device which is characterized by densely packed fins that enable high levels of heat dissipation from the small volume occupied by the fan sink, with the small volume characterized also in some of the embodiments by low axial height or axial thickness of the fan sink, which is compensated by spreading the components composing the heat-sink in a radial direction and parallel to the PCB, thus enabling the reduction of the distance between the PCBs within the cabinet housing the components.

It should be noted that references to elements or components of the invention in the singular also apply to the plural, wherever relevant, and such usage does not imply, nor is it intended to limit the invention to any number or quantity of such elements or components.

Although the mounting surface for the heat-generating component is intended to apply to any supporting substrate types as is known to those skilled in the art, in a preferred embodiment of the invention, the mounting surface is a PCB.

For descriptive purposes only and without limiting the invention to any specific orientation in space, the PCB side is defined as the lower or bottom side or any of its synonyms, such as downward, and the like, and accordingly, the surface of a cooling device that is adapted to become attached to the heat-generating component is the lower side/surface/plane or bottom side/surface/plane or downwardly facing side/surface/plane or any relevant synonymous term associated with the surface of the cooling device. Accordingly, the side opposite to the bottom is the top side/surface/plane or upper side/surface/plane or upwardly facing side/surface/plane or any relevant synonymous terms.

The directions given in the text with reference to relationships of components of the invention are based on an orthogonal cylindrical coordination system wherein: The axial direction is one preferably perpendicular to a PCB in relation to the upper surface of a heat-generating component and to the bottom surface of a cooling device that is thermally attached to the heat-generating component. The axial direction preferably coincides with the direction of the fan's rotating axis and preferably also, when applicable, with the symmetric axis of a cooling device, with both preferably coinciding with other symmetric axes as is hereinafter described.

The radial direction (see key in FIG. 1B). is the direction perpendicular to the axial direction and generally means radially and outwardly oriented unless radially and inwardly oriented is specifically indicated. As a coordinate, the radial direction is applicable also to non-symmetric and non-circular objects and assemblies of objects as exemplified in variously described embodiments of the present invention

The tangential direction is the direction perpendicular to the radial direction such that both coordinates are in a plane perpendicular to the axial direction.

“External” to an object or assembly is defined herein as being outside and external to the peripheral envelope or contour of the object or assembly, such as the cooling device, and generally means out of the space occupied by the components composing the cooling device or the cooling device itself, in the indicated direction or generally in all directions, as the case may be.

“Internal” signifies inside the space occupied and/or the space surrounded or enclosed, by the components comprising the cooling device or the cooling device itself, and in any direction radially or perpendicular to the cooling device, as the case may be.

Unless otherwise indicated, the footprint of an object composing the cooling device or the cooling device footprint as a whole, is defined as the downward disposed projection of the object contour or contours when viewed parallel to the axial direction from top to bottom, or conversely, the upward disposed projection of the object contour or contours when viewed parallel to the axial direction from bottom to top, as the case may be.

The term “fan” is used in general to describe also blowers, unless a centrifugal blower or an axial fan is specifically intended, whereupon the specific and respective name is used.

Attached surface(s) or object(s), is defined as a surface(s) and/or object(s) that is connected by a direct attachment or through an intermediate object, be it either a thermal connection which is not intended to carry loads—although it might be capable to carry loads to some extent, or a load-bearing mechanical connection intended to carry loads—although it might be capable to transfer heat to some extent, or both thermal and mechanical connections carried out simultaneously.

### BRIEF DESCRIPTION OF THE DRAWINGS

For a better understanding of the invention in regard to the embodiments thereof, reference is made to the accompanying drawings (not to scale) and description, in which like numerals designate corresponding elements or sections throughout, and in which:

FIG. 1A is a symmetrical half cross-section view of a preferred embodiment of the present invention comprising a cooling device with a low-profile, forced-airflow-cooled heat-sink;

FIG. 1B is a symmetrical half, cross-section view of the cooling device of FIG. 1A, but shown with a heat-sink comprising stacked plate fins of diminishing radius;

FIG. 1C is a top view of the cooling device from FIGS. 1A and 1B, but for clarity, shown without a finger guard;

FIG. 1D is a bottom view of the cooling device of FIGS. 1A and 1B;

FIG. 1E is a view of the finger guard component of the cooling device of FIGS. 1A to 1D;

FIG. 1F is a bottom view of the cooling device of FIGS. 1A to 1D shown with a filter mounted on two supporting extensions;

FIG. 1G is a cross-section detail View 1-1 from FIG. 1F showing the supporting extensions used for mounting a filter;

FIG. 1H is a symmetrical half cross-section view of another embodiment of the invention of FIG. 1A;

FIG. 1I is a symmetrical half cross-section view of a further embodiment of the invention of FIG. 1A;

FIG. 2A is a cross-section view of another embodiment of the invention from FIG. 1 utilizing pin fins protruding from a rigid, inclined base;

FIG. 2B is a top cross-section detail View 2-2 of the invention from FIG. 2A;

FIGS. 3A to 3N illustrate, in detail, various configurations of indented and perforated plates comprising preferred embodiments of elements of the heat-sink of the present invention;

FIGS. 4A to 4G illustrate another embodiment of the invention provided with side-mounted and internally mounted blowers;

FIGS. 4H to 4L illustrate various types of air-directing means for gradually changing the direction of airflow in preferred embodiments of the invention in accordance with the principles thereof;

FIGS. 5A to 5J illustrate yet other configurations of an embodiment of the invention comprising perforated, cup-shaped plates;

FIGS. 6A to 6C illustrate still other embodiments of the invention comprising deep-drawn perforated plates shaped as saucers with their walls monolithic extensions of their bases;

FIGS. 7A to 7G illustrate various double-walled embodiments of the invention;

FIGS. 8A to 8D illustrate preferred solid block embodiments of the invention;

FIGS. 9A and 9B illustrate yet other embodiments of the invention comprising stacked and oblique plates;

FIGS. 10A and 10B are a cross-section View 23-23 and a top axial cross-section view of yet another embodiment of the invention comprising oblique spaced-apart, continuously folded, perforated strip-fins;

FIG. 10C is a cross-section of a plate fin cut before mounting on a solid core;

FIGS. 10D and 10E illustrate a preferred method of mounting continuously folded, perforated strip-fins onto a core in accordance with the principles of the invention;

FIG. 10E illustrates another step in the method of forming a heat-sink with continuously folded, perforated strip-fins; and

FIGS. 11A and 11B are a radial cross-section View 24-24 and a top view, respectively, of an embodiment of the invention comprising meshed, woven-metal grid fins.

### DETAILED DESCRIPTION OF THE PREFERRED EMBODIMENTS

With current technology, mass manufacturing of a heat-sink of up to 40 mm axial height, densely populated by through-perforations of less than 12 mm-square footprint area, is most economical by utilizing any of the combination of stacked perforated and/or indented plates hereinafter described. Notwithstanding, the present invention is not limited to embodiments composed of stacked perforated and/or indented plates, but, can be made of any commonly used material as is known to those skilled in the art. For example, a heat-sink may be made of a solid and relatively thick perforated graphite block, wherein due to the softness of the material, it can be densely perforated or fine-blanked by utilizing currently available high output perforating or fine-blanking processes.

Extruded perforated tubing can also be considered, providing the perforations are sufficiently small to provide the equal surface area as in the perforated stacked plates of a preferred embodiment of the invention. In a preferred embodiment of the invention, the footprint area of the perforations populating a discrete heat-conducting element is cumulatively larger than 30% of the footprint area of the discrete element itself.

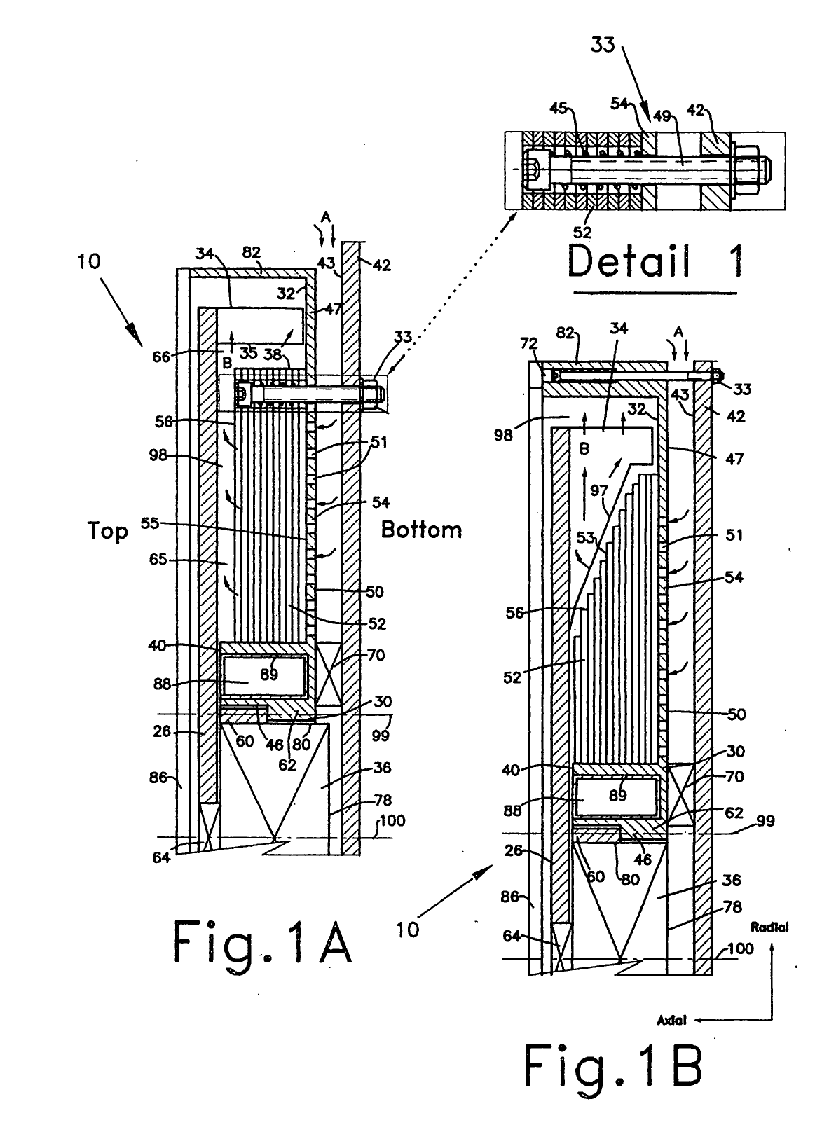

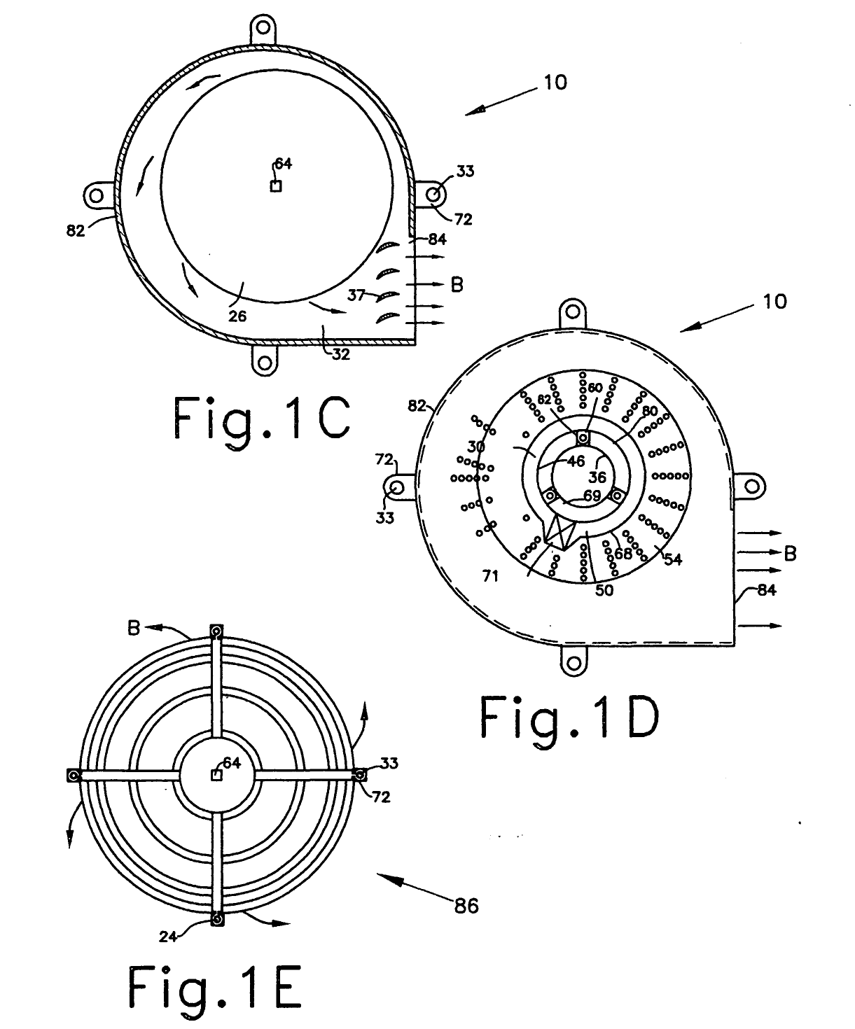

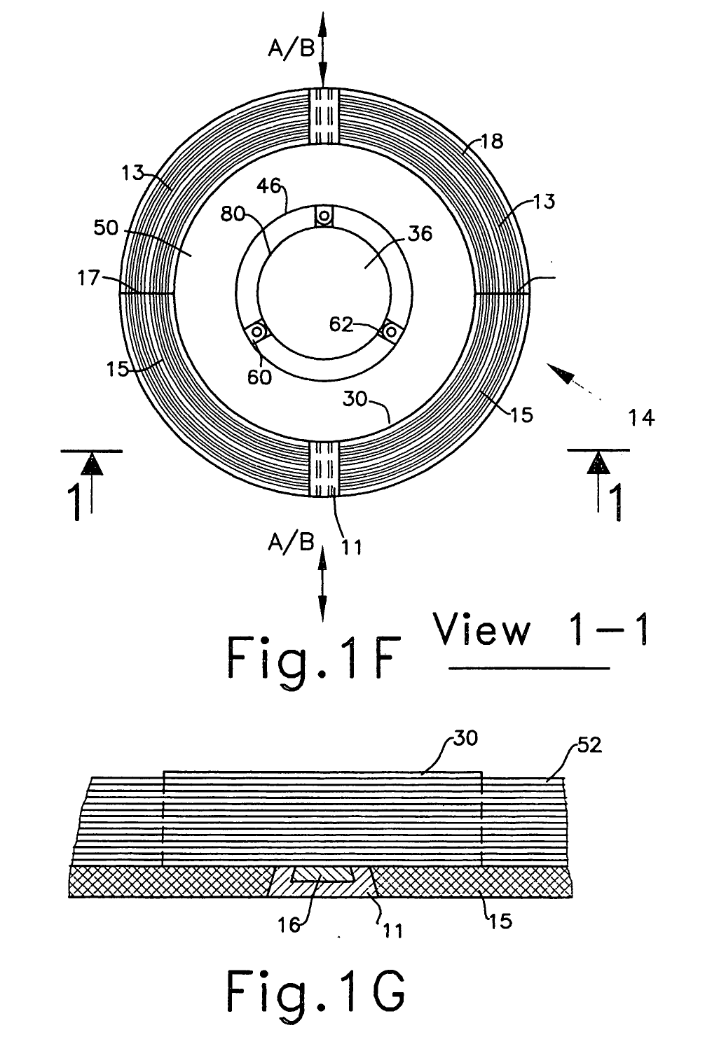

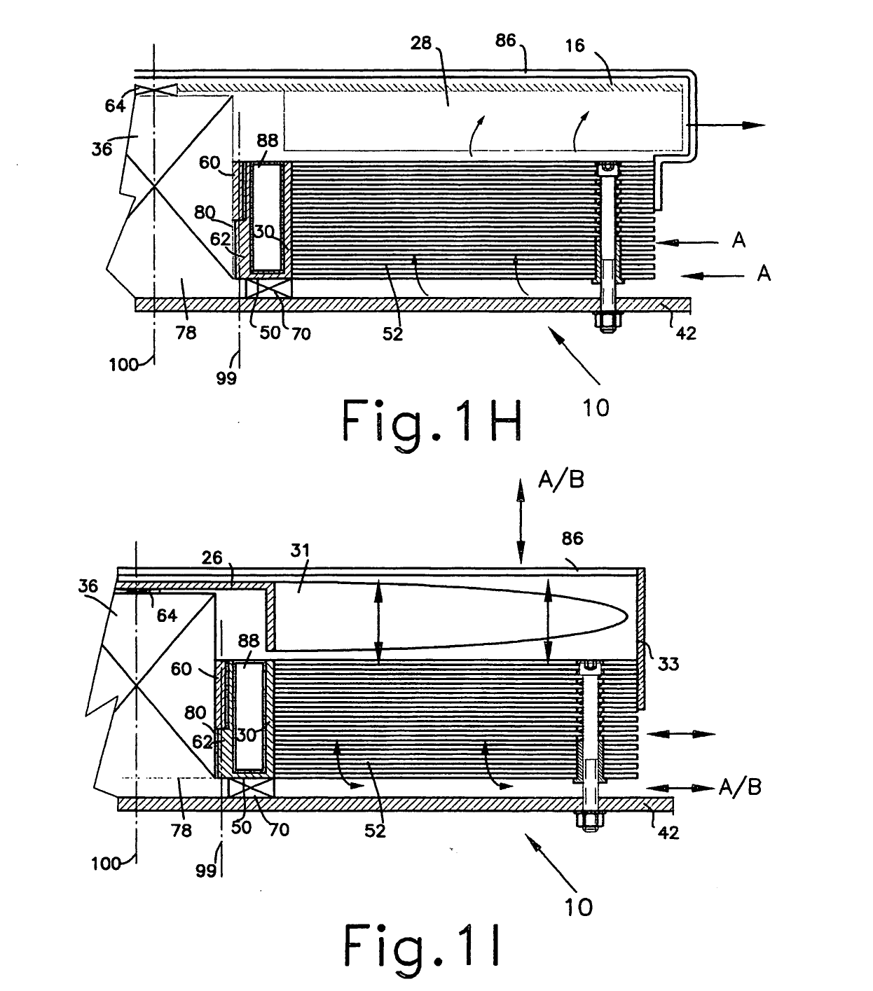

FIG. 1A is a symmetrical half cross-section view of a cooling device with a preferred embodiment of the present invention comprising a low-profile, forced-airflow-cooled heat-sink.

Cooling device 10 is shown mounted on a mounting surface, such as PCB 42, and comprises a central annular core 30 supporting identical, circular, perforated, stacked plate fins 52.

An electrically operated blower, indicated by its motor 36, upon whose hub 64 is supported impeller 26, peripherally and symmetrically carries radial/centrifugal blades 34 which rotate externally to the plate fins 52.

Motor 36 is wholly disposed in a through-bore indicated by its envelope, wall 46, symmetrically provided in the symmetrically and centrally located, annular heat-conducting central base 30, hereinafter termed synonymously as: core, base, central base or central core-base, composing the heat-sink of cooling device 10.

The core 30 is confined between parallel top planar surface 40 and bottom base planar surface 50, with both surfaces preferably vertical to the congruent symmetric axis 100 for both core 30 and cooling device 10. The core 30 supports, by press-fit connection, tightly stacked, circular perforated plates fins 52 which are parallel disposed to planes 40 and 50.

In the embodiment of the invention illustrated in FIG. 1A, the perforations in each plate of fins 52 precisely overlap those in adjacent plates making the air passages relatively uniform in length They also sustain a uniform mean-velocity vector of air flowing along the whole length of each individual passage.

The fins 52 are shown, only by way of example, as having equal dimensions, but it is understood that modifications may be made which are obvious to those skilled in the art without detracting from the principles of the invention. The centrifugal blades 34 of the impeller 26 are centrally and symmetrically disposed in annular, orthogonal cylindrical geometry, and rotate externally to the space occupied by the fins 52. The footprint of fins 52 is symmetrically enclosed by the footprint of the supporting section of the annular blades 34.

At least one heat-generating component 70 is mounted on the PCB 42, eccentrically located in respect to symmetric axis 100, core 30, and through-bore wall 46. A heat pipe 88 is circumferentially embedded in the core 30, above the heat-generating component 70 to ensure circumferential, and nearly uniform, temperature around core 30. Incoming air, shown by arrows A, enters through perforations 51 made in the bottom surface 55 of the stacked plate fins 52, congruent with, in a preferred embodiment of the invention, the perforations made in base plate 54.

Cooling device 10 is connected to PCB 42 by an attachment means 33, most commonly an arrangement of screws and springs, as shown in enlargement in Detail 1 of FIG. 1A, rotated by 90°. The screws and springs arrangement provides a controlled pressure at the contact area of the heat-sink 10 and the heat-generating component 70. As is known by those skilled in the art, when properly tightened, the screws in attachment means 33 provide proper connecting pressure between heat-generating component 70 and surface 50 of cooling device 10, thus leading to proper thermal conduction from heat-generating component 70 to the core 30. At the same time, cooling device 10, in respect to component 70 and the PCB 42, is retained in a stable position.

FIG. 1B is a symmetrical half cross-section view of the cooling device of FIG. 1A, but with an embodiment of the invention comprising stacked plate fins of diminishing radius.

In FIG. 1B the free ends of plate fins 52 form an oblique surface, leading to the forming of plenum 98 where it can be seen that the radially increasing volume of plenum 98 is in conformity with the radially increasing airflow volume provided in the direction of air (indicated by arrows) exits from the perforations in plate fins 52. The blades 34 can be shaped either of uniform size as in FIG. 1A or, as in FIG. 1B where they have an addition of an oblique section whose edge 97 conforms with the oblique ends 53 of plate fins 52.

Exhausted air (arrows B), after becoming heated by plate fins 52, is sucked into the blades-space through plenum 98 and directed to flow in a specific direction (as per the arrows B) to disperse the heat generated by heat-generating component 70 mounted on PCB 42.

Outwardly protruding motor supports 60 extend from the top side of the outward symmetrical extreme motor envelope 80, and are attached by any attachment means as is known to those skilled in the art. In the example shown in FIG. 1, attachment is by means of bolts, as is indicated by the axis line 99 of their symmetric axes, to matching inwardly protruding motor supports 62 that extend from the inner side of the annular central base 30, namely from the through-bore walls 46. The dimensions of through-bore walls 46 are wholly defined by the extreme through-bore envelope which coincides with the through-bore walls 46 and which is centrally and symmetrically provided in the core 30 to accommodate motor 36.

Motor 36 is wholly disposed within the space of through-bore walls 46 so defined, preferably with an air gap provided between the extreme motor envelope 80 and the envelope formed by the through-bore walls 46, preventing a direct contact between motor envelope 80 and the hot, internal core envelope congruent with through-bore walls 46, and enabling the flow of cooling air around motor envelope 80.

Motor 36 is embedded within the space confined between the inwardly extensions of top planar surface 40 and bottom planar surface 50, with impeller 26 disposed outside the space of through-bore walls 46 at a specifically designed clearing distance 65 from the upper plate face 56 to define the height of the air plenum 98. Impeller 26 is rigidly attached to the cylindrical motor envelope 80 exposed to the surrounding air for the purpose of providing improved heat dissipation. The bottom face 78 of motor 36 can be coplanar with plane 50 or extended downwardly beyond plane 50 out of the space enclosed within through-bore 46 provided that it does not interfere with any component mounted on PCB 42 within the footprint of motor 36.

The cylindrical motor envelope 80, in a preferred embodiment of the invention, is made from heat-conducting metal, although any suitable heat-conducting material can be used. Motor 36 is cooled by exposing it to the air that flows around the cooling device 10 and within the space between motor envelope 80 and the through-bore walls 46. The moving air, shown by arrows, is sucked into plenum 98 through the gap 65 between plane 40 and the bottom side of impeller 26. This provides for improved dissipation of the heat generated by the bearings and windings (not shown) of motor 36. This heat, when not properly dissipated, leads to excessive warming of motor 36 and reduction of its operating life.

In a preferred embodiment of the present invention, a thin coating of a thermal adhesive is applied to the surfaces to be contacted, a technique known to those skilled in the art. Applying appropriate heat-conducting interfacing material, such as a thermal adhesive coating, between the attached surfaces commonly enhances the thermal conductivity of the attachment.

In the embodiments of the invention shown in FIGS. 1A and 1B, a suitable press-fit is applied to core 30 which then becomes attached mechanically and thermally to both cooling device 10 and the annular, solid, perforated fins 52. Fins 52 in various embodiments, comprise any of the following configurations: perforated plate fins, indented plate fins, meshed wire-grid fins, pin fins, extruded perforated tubing sections, perforated solid block, plate fins thermally fused into a block, and any combination thereof as will be hereinafter described in detail.

The bottom surface 55 of fins section 52, in one embodiment of the invention, comprises a perforated plate and is preferably coplanar with the bottom surface 50 of core 30. Non-perforated sections of the bottom surface 55 can also serve as suitable thermal attachment areas to at least one heat-generating component 70 when the location of such heat-generating component extend beyond the footprint of core 30.

Distance 65 between plane 56 and the bottom side of the impeller 20 defines the height of an air outlet plenum 98 of a uniform height 65 for the warmed-up air exhaled from the perforated fins, as will be hereafter detailed.

The free lower ends 20 of blades 34 are minimally spaced from surface 32 of the non-perforated section 47 which outwardly extend from the bottom plate 54. Section 47 supports at its periphery a frame 82, which is preferably a bent, continuous solid extension of section 47. Frame 82 supports the finger guard 86. The internal sides 35 of blades 34 are radially spaced from the external periphery 38 of the fins 52 at a sufficient radial distance to enable the air to change its flowing direction when exhausted from plenum 98 and interact with the whole blades surface, as is indicated by arrow B. The axial dimension 35 of the blades 34 is referred hereinafter as the blades height, or the blades axial height, while the blade radial width marked by 20 is referred as the blade width, or the blade radial width and is not geometrically limited and can be set according to the designed performance of the system. For a specific rotating speed the radial width increase is associated with increased pressure and power consumption, which the motor 36 has to provide.

In all embodiments of the invention wherein the centrifugal blower blades are disposed externally to the fins, such as fins 52 as in FIG. 1, the necessary high pressure needed to overcome the pressure losses generated by the perforated plates, is provided by the large rotating radius of blades 34 which rotate at a relatively low rotating velocity and thus generate a low level of noise. The high pressure enables utilization of densely perforated plate-fins with a small air-flow cross-section and accordingly, an increase in the contact area between the air and the hot fins without reducing the optimal air velocity within the perforations. This embodiment allows reducing the overall axial height of a heat-sink to a height as low as the motor component, and makes the cooling device of the present invention especially advantageous for use in enclosures with densely packed PCBs.

The high pressure provided by the externally rotating blades enables overcoming the resistance provided by densely packed fins and, in some embodiments, also that offered by an air filter, while in association with a properly sized and located air plenum, air inlets and outlets, as is hereinafter described, the high pressure ensures that all the face surface of the fins become subjected to optimal airflow volume and air velocity, as a function of the local temperature of the fins and the area of the perforated surface.

As was mentioned above, due to the eccentric and asymmetric location of the heat-generating component 70 in respect to the annular core 30, an undesirable temperature gradient is formed from the heat-generating component 70 along the two halves of annular periphery of core 30. This gradient propagates into fins 52 and leads to an undesirable reduction in the heat-dissipating capacity of cooling device 10.

In order to reduce such a temperature gradient, a heat pipe 88, as manufactured, for example by Thermacore Inc., Lancaster, Pa., is utilized to transfer the locally generated heat along the periphery of core 30 at a temperature gradient that is generally of an order of magnitude smaller than the gradient existing along a geometrically identical heat path, composed only from rigid aluminum or copper.

Heat pipe 88, as used in a preferred embodiment of the invention, is a sealed copper/aluminum/stainless steel pipe, most commonly filled with water under low pressure, that enables the water to boil at low temperature when heat dissipated from heat-generating component 70 penetrates into heat pipe 88. The vapor flows from the heat source to the cooler sections of heat pipe 88—the condenser—where, in accordance with the latent heat absorbed from heat pipe 88 into core 30 along most of the circumferential length of core 30, the vapor condenses. The condensed water is returned by capillary action within the internal, circumferential, porous wick layer, to the evaporating area above heat-generating component 70, where the cycle repeats itself as long as heat flows into the evaporator section of heat pipe 88 and is removed at the condenser section.

The annular heat pipe 88 fits into an annular channeled groove 89 defined by the wall 89 (as shown in FIGS. 1A and 1B) provided in the periphery of core 30 around wall 46 of the through-bore in cooling device 10, with the open side of groove 89 upwardly facing. The cross-section of heat pipe 88 matches, at a suitable press fit, the cross-section of groove 89, forming a good thermal-conducting attachment between the walls of heat pipe 88 and the walls of groove 89. Heat pipe 88 can be press fitted into groove 89 as is, or after becoming encapsulated by heat-conducting paste or a soldering flux, to enhance the thermal conductivity of the attachment between heat pipe 88 and the walls of groove 89.

In addition to the main annular heat pipe 88, smaller heat pipes can optionally be embedded, radially or tangentially, within the fins section 52, reducing the radial heat spreading resistance without unduly increasing the overall weight of the cooling device.

FIG. 1B illustrates a full top view, but not to scale, of the embodiment of the invention of FIG. 1A, shown without a finger guard for clarity.

Exhaust air B from the blades 34 is directed by frame 82 and vanes 37 to flow in a specific direction, optionally, through openings in frame 84 and between vanes 37 provided in this embodiment of the invention. Note that supports 72 can be utilized for mounting the heat-sink with connecting means 33, such as the bolt shown in FIG. 1A and in the Detail view.

In the embodiment illustrated in FIG. 1B, surface 53 is preferably step-wise oblique by mounting plates provided with decreasing radius, leading to radial decrease in the axial thickness of fins section 52. The maximum thickness is near the core 30 and the thickness decreases towards a minimum at the external periphery of fins section 52, near blades 34.

It should be noted that, as in the preferred embodiment of the invention as shown in reference to FIG. 1A, the rotating axis of the motor 36 is coincidentally disposed in common with the symmetric axis 100 of the through-bore walls 46 and of cooling device 10 as a whole.

The annular planar surface 50 at the bottom side of the core 30; or at least a section thereof; or extension 71 thereof (as described and explained in FIG. 1D) is adapted to be attached to at least one heat-generating component 70 which is shown mounted directly on the upper surface 43 of the PCB 42, as is common with surface mounted technology (SMT) devices. Optionally, the heat-generating component 70 is mounted on a socket (not shown) and the socket is then mounted on the PCB 42. Consequently, the contact surface between the heat-sink 10 and heat-generating component 70 is eccentrically disposed in respect to symmetric axis 100 of cooling device 10 and core 30.

FIG. 1C is a top view of the cooling device from FIGS. 1A and 1B, but for clarity, shown without a finger guard. The airflow is in accordance with the arrows in chamber 32. Note that the air-directing means, in this embodiment of the cooling device, vanes 37, direct the airflow for the exhaust air (indicated by arrows B) through the opening 84 in wall 82 to the outside air. Four supports 72 are provided for mounting the heat-sink with attachment means, such as shown in FIG. 1A in detail.

FIG. 1C illustrates also the annular space 69 that exists between the envelope 80 of motor 36 and the through bore internal envelope 46 that serve as passage for the motor cooling air. The bottom ends of the motor supports 60 and 62 are also visible. The exhaust from the heated air follows a path along the enclosure 82 where it exits the heat-sink 10 as indicated by arrow B.

FIG. 1D is a bottom view of the cooling device of FIG. 1A.

Note that in FIG. 1D the footprint of a heat-generating component 70 (marked by X) is, by way of example, shown larger than the radial width of the annular core 30, whereupon an extension 71 at the bottom side of the core 30 is provided. Extension 71 can be constructed with its bottom side coplanar with the bottom side 50 of core 30 or it can protrude downwardly (not shown) within the foot print of core 30 or outside the footprint of core 30 to enable contact of other heat-generating components (not shown) with the upper sides of their cases at a lower level than that of the extended heat-generating component.

The addition of extension 71 provides a thermally conducting attachment between the whole surface of heat-generating component 70 and the core 30. Such extensions can be positioned and sized in accordance with the locations and sizes of the plurality of heat-generating components mounted under the footprint of the core and its relevant extension.

FIG. 1E illustrates a view of a conventional finger guard adapted for use with heat-sinks having a fan element. The finger guard 86 is applicable to all the embodiments of the invention described herein to prevent accidents or injury from exposed blades. Finger guard 86 is adapted to be mounted with attachment means (not shown) that match the tab supports 72 shown in FIGS. 1B and 1C.

The finger guard 86 is so constructed as to provide for the expulsion of air in all directions as marked by arrows B. Finger guard 86, as is known to those skilled in the art, is most commonly a wire mesh or a punched thin plate, which is applied whenever safety codes demand its use to prevent finger contact with a rotating impeller. When installed on the top of the frame 82 at a minimal distance from impeller 20, the axial thickness of finger guard 86 increases the overall axial height of cooling device 10. If noise reduction becomes an important issue, finger guard 86 can be replaced by a solid cover which reduces noise propagation without affecting cooling device performance.

FIG. 1F is a bottom view of the cooling device from FIGS. 1A to 1D shown with a filter mounted on two supporting extensions.

In FIG. 1F, air filter 14 is mounted on a dovetail arm 16 extending from the lower end of the core 30. The filter 14 is composed of two symmetrical halves marked generally by 13 and 15, which contact each other along axis line 17. The filter 14 is mounted and dismantled by sliding it along its support frame 11 on the matching arm 16 in directions indicated by arrows 19. The filter footprint coincides with that of the fins 52 forcing the air inhaled into the fins space to pre-cross the filter 14. Filter 14 helps to maintain long-term preservation of the efficiency of the heat-sink by trapping air particles which might enter the tight spaces between the heat-conducting plates. Also, the small perforations in the fins and base plate 55 are protected from contaminants so as to maintain the heat-dissipation capacity of the heat-sink.

FIG. 1G is a cross-section detail View 1-1 from FIG. 1F showing the supporting extensions for mounting filter 14 in relation to the core 30 and fins 52 of the heat-sink, and an enlarged view of the dovetail arm 16 seated in supporting frame 11.

FIG. 1H illustrates a symmetrical half cross-section view of a further embodiment of the invention of FIG. 1A. The cooling device 10 is shown provided with over-large top-mounted axial blades 28 extending outside the perimeter of the plate fins 52 and a large motor 36 embedded within an annular core 78. Incoming air A passes through the spaced-apart plates as well as between the plates 52 and the mounting surface of PCB 42 to cool the heat-generating component 70. Air, pulled by suction through plates 52 by blades 28, is exhausted from the cover 86 as indicated by arrow B.

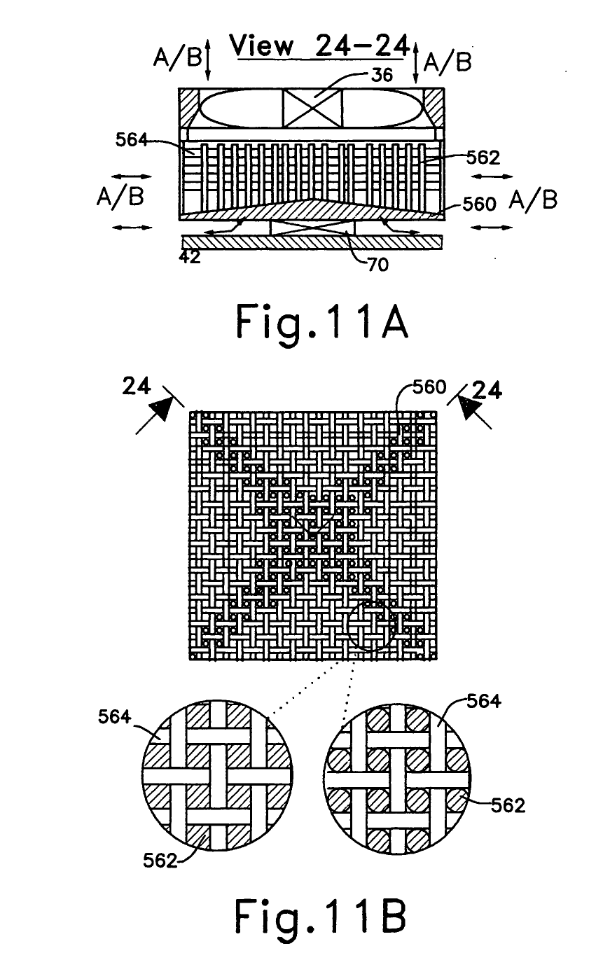

FIG. 11 is a symmetrical half cross-section view of a further embodiment of the invention of FIG. 1A. The cooling device 10 is shown provided with covered, top-mounted radial blades and a large motor 36 embedded within an annular core 78.

The cover 86 on cooling device 10 enables air to be inhaled/exhausted as indicated by arrows A/B. Shown as an option are spaced-apart plate fins 52 which also enable air inhaling/exhaling through the space between the fins 52 as indicated by arrow A/B, in addition to the air inhaled/exhaled through the fin perforations themselves.

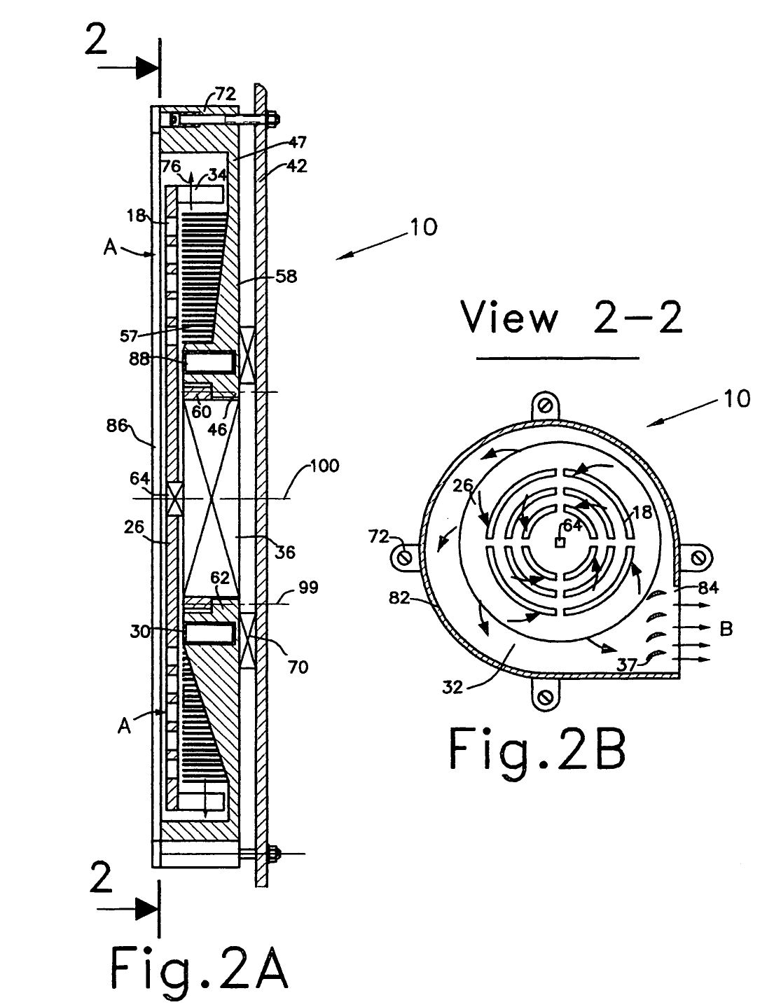

FIG. 2A is a cross-section view of another embodiment of the invention from FIG. 1 utilizing pin fins protruding from a rigid, inclined base. This embodiment of the invention facilitates one-piece forging. The thickness of the base of the heat-sink gradually decreases toward the circumference. The impeller of the blower comprises openings enabling through-air flow into the space between the fins.

FIG. 2A illustrates a low-profile cooling device 10 similar to the embodiment in FIG. 1 wherein the plate fins in the embodiment in FIG. 1 are replaced by a solid conical base 58 with its thickness decreasing radially from the supporting annular core to its external periphery. Alternatively, base 58 may be constructed with a uniform thickness and with fins 68 of a uniform height.

The impeller 26 of the blower comprises a blade-free central section which is through-slotted by air passages and provides impeller-through-airflow into the space between the pin fins as well as thermal contact with the air-exposed surface of the pin fins when the impeller 26 rotates.

The base 58 is populated by upwardly protruding pin-fins 57. Impeller 26 is provided with through-air flow slits 18 enabling air inflow through the finger guard 86 and the impeller 26 into the space between the fins 57. An advantage of this embodiment of the invention is that it enables the manufacturing of a heat-sink by one-piece forging.

FIG. 2B is a top cross-section detail View 2-2 of the invention from FIG. 2A. It is shown without a finger guard to indicate the through-air flow B into the passages in the impeller 26. The through-air flow B is directed into slits 18 provided in impeller 26 which enables the air to flow into the space between the pin-fins 57 (see FIG. 2A) and is further guided by blades 37 to exit through the opening 84 in frame 82.

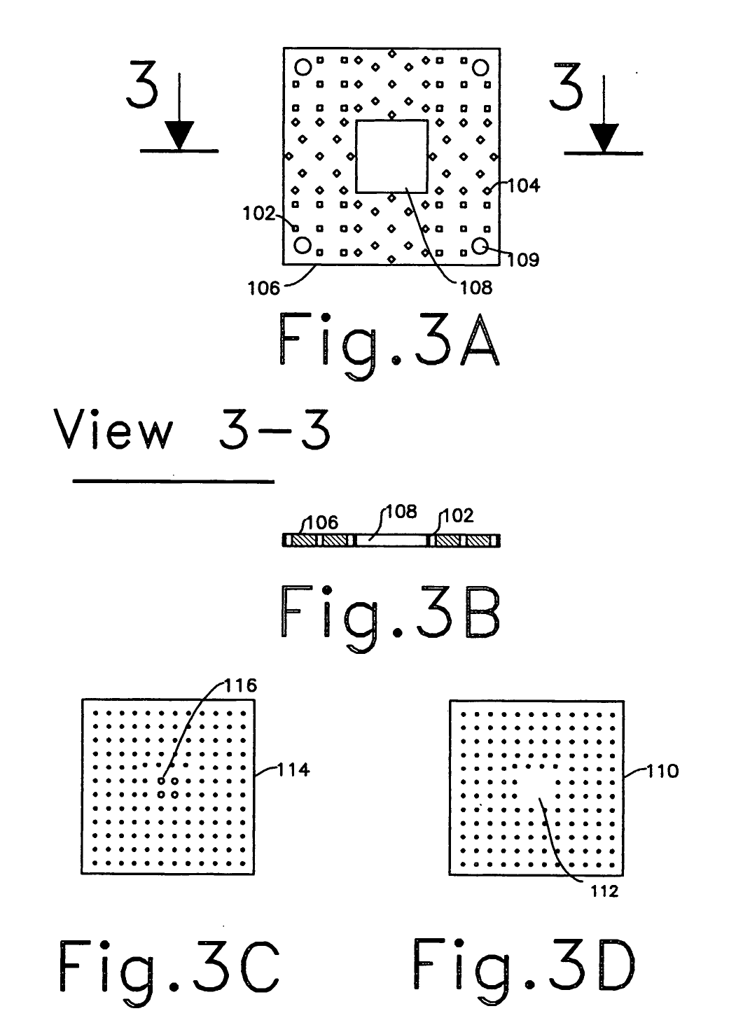

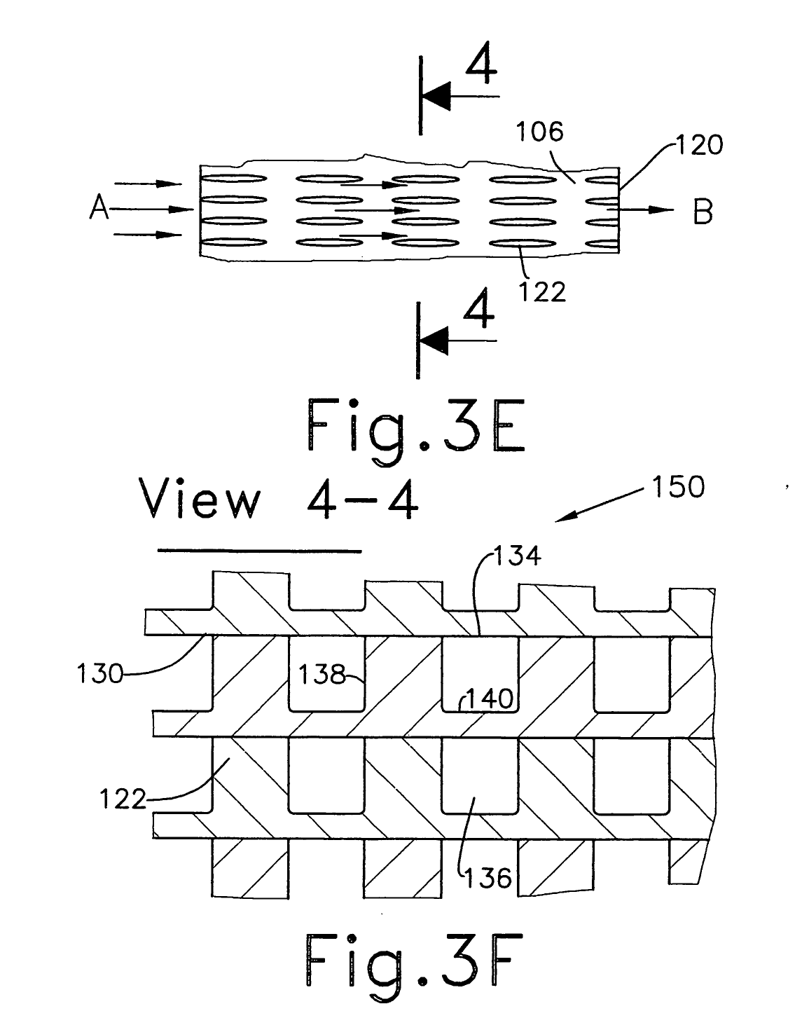

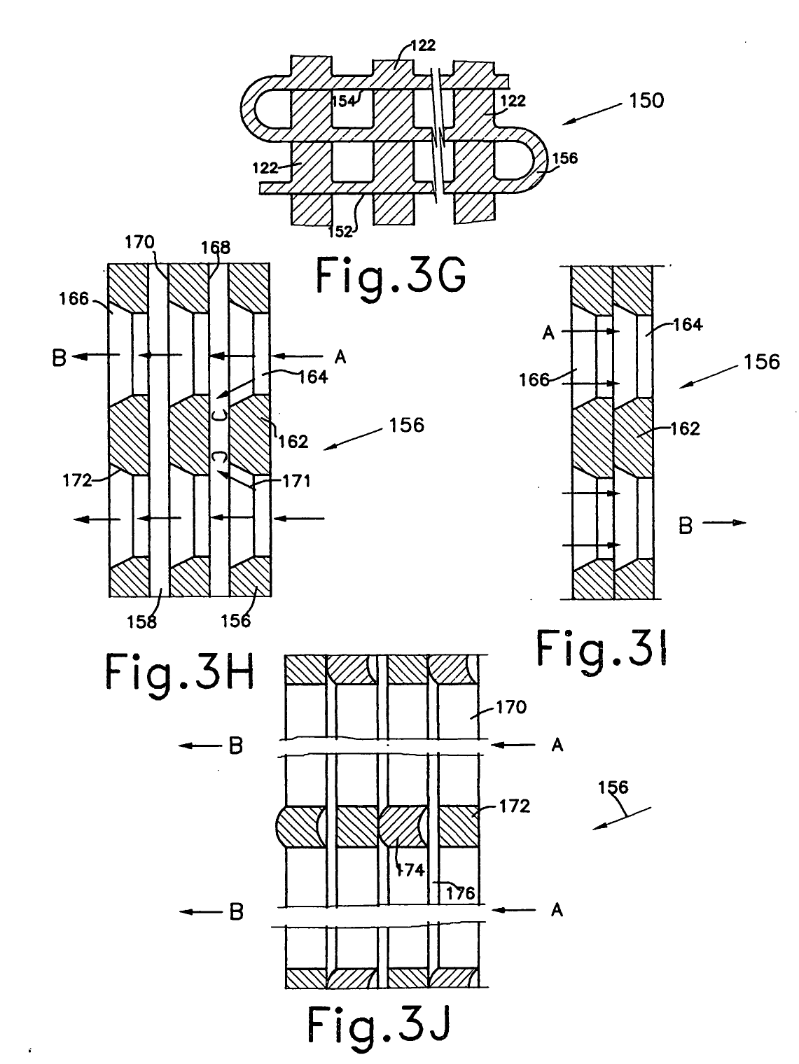

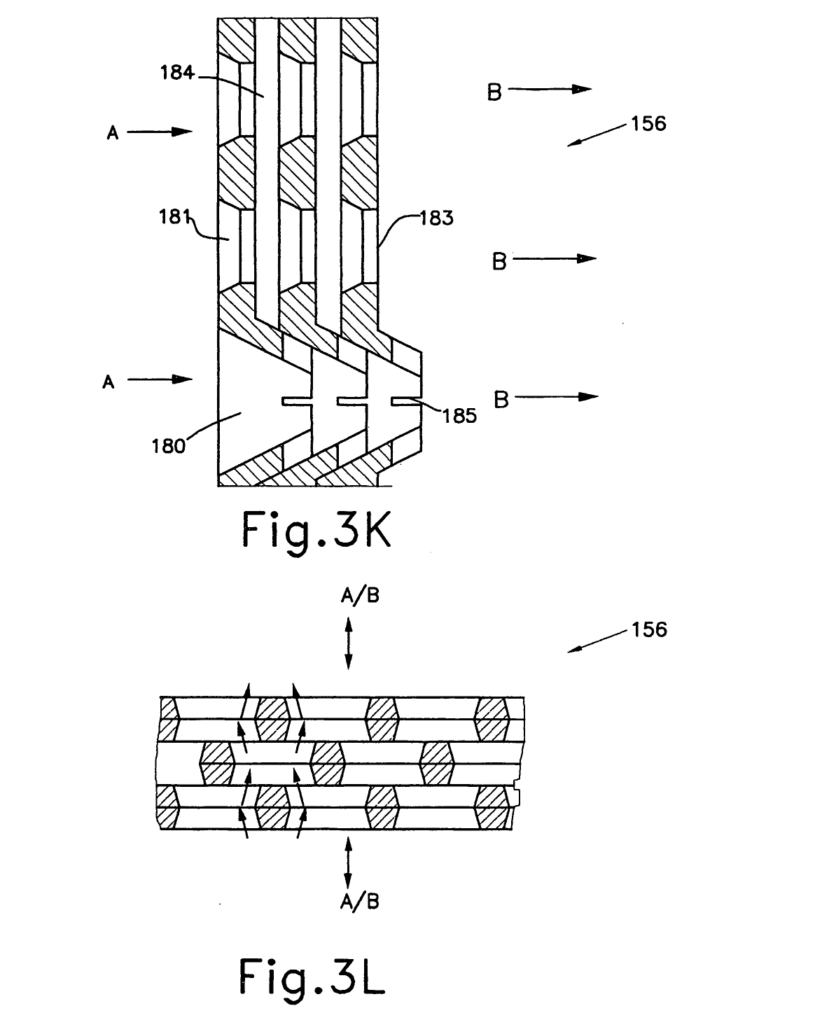

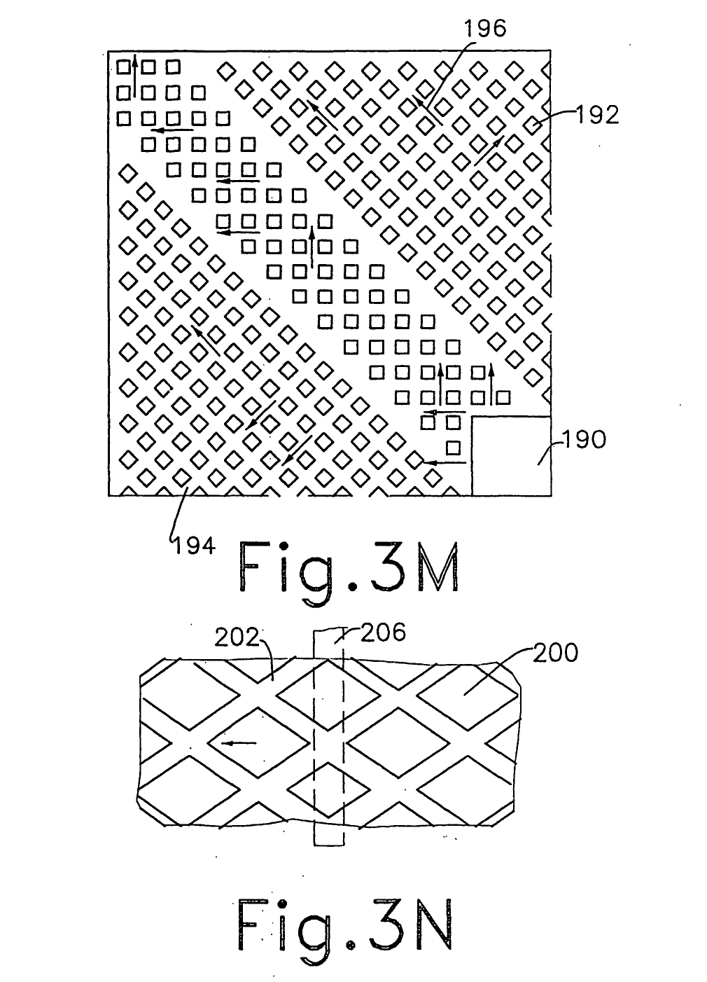

FIGS. 3A to 3N illustrate, in detail, various configurations of indented and perforated plates comprising preferred embodiments of elements of the heat-sink of the present invention.

These elements of heat-sinks are suitable for use with their respective components as described above and further disclosed below.

The central section of the plates, in accordance with the principles of the invention, is cut away adapting the plates for press-fit mounting on a heat-conducting core. The core can be either monolithic solid rod or centrally and conically bored or a hollow heat pipe, of any cross-section. The plates can be mounted tightly stacked or spaced apart, or any combination thereof.

The central section is left uncut and non-perforated, adapting the tightly stacked plates to become thermally fused, at least at their centers, into a heat conducting solid block by applying suitable pressure and temperature, with or without employing a thin cladding layer with lower melting-temperature than the substrate plate.

The central section of the tightly stacked plates is suitably perforated with the perforations cast-filled with brazing or a soldering agent, turning the fused block into a solid, heat-conducting core.

The central section of the tightly stacked or spaced-apart plates, or any combination thereof, is perforated in a manner providing for advantageous mounting by press-fitting it onto a pin-fin heat-sink.

The stacked plates can be structured as a continuously folded strip or a plurality of discrete plates, or any combination thereof. The plates can be tightly stacked or spaced apart, or any combination thereof, from the same material or from different materials such as any combination of layers of aluminum and copper plates, and the like.

Each through-perforation is circumferentially defined by bordering solid sections, which are referred to in the industry as bars or bridges, terms hereinafter utilized synonymously. In the present invention, each bar serves the dual task of radial heat spreaders from the heat source to the edges of the plates and as heat dissipaters to the air.

In some embodiments of the invention, the footprint of the perforations is only partially cutaway or is entirely left uncut, with the uncut section(s) outwardly indented to protrude from the plate surface forming a through-flow perforation of sufficient flow-through footprint as to accord with the principles of the invention in its various embodiments, as described below.

In general: the industry rule-of-thumb is that the width of the bars and perforations footprint must be sized near to the thickness of the perforated plates to enable mass manufacturing without the bars and the cut fins becoming too frequently broken. In a preferred embodiment of the invention, the footprint area of the holes comprising the perforations is less than 12 mm² and is less than half the area of the walls of each of the respective perforations.

Furthermore, the perforations need not necessarily be uniform in size or shape, but the whole face area of the perforated section is preferably covered with perforations or indentations or combinations of either adapted to conform to the type of air-moving means utilized in the cooling device. In accordance with a preferred embodiment of the invention, the ratio between this whole face area and the perforations area forming the airflow passage through the plates of a heat-sink is at least 0.03.

The plates described herein are of any of the following configurations and any relevant combination thereof enabling construction of the various embodiments of the invention as described below by employing any of the following applicable types:

a) Perforated plates with perforations of any shapes, sizes, uniformly or non-uniformly populating patterns, with the all bars disposed within the plate or the bars or part thereof wholly or partially outwardly protruding out of the plate surface.

b) Wire mesh, of any weaving pattern and wire cross-section.

c) Welded or flattened wire-mesh of any weaving pattern and wire cross-section.

d) Indented plates with blind or open indentation.

e) Indented and perforated plates in any proportions and of any shapes, sizes, uniformly or non-uniformly populating patterns.

f) Expanded perforated plates or flattened expanded perforated plates with perforations of any shapes, sizes, uniformly or non-uniformly populating patterns.

As is known to those skilled in the art, although only preferred embodiments of perforated/indented plates/strips are illustrated and described herein, any perforated/indented plate/strip which can be manufactured by any perforating/indenting process at desired thickness, perforations size, shape and populating pattern, can be employed in the making of the invention provided that, in the case of stacked plates, they are provided with the nominal airflow and air-velocity in compliance with the capabilities of the air-moving means for moving air, namely the air volume and pressure at the intersection point of the operating curve for the given air-moving means, and that the resistance curve of the stacked plates complies with the nominal air volume needed to remove the nominally generated heat at a nominal ambient temperature.

With reference now to FIG. 3A, a top view of a perforated plate 106 is displayed. In this preferred embodiment of the invention, the perforations 102 and 104 have a square footprint preferably disposed with different orientation in different sections of the plate 106 in respect to the main symmetric axes, in a manner that ensures that the heat flow direction-vector in each bar (the sustaining plate surface between the perforations 102/1104) comprises a radial component, and accordingly each bar serves simultaneously as radial heat conductor from the core (not shown) to the external edge of the plate 106 and as a heat dissipater to the flowing air through the perforations 102/104. The center of the plate 108 is cutaway adapting it to be press fit on a matching core (not shown). Four larger holes 109 are adapted to serve as mounting holes for an attachment means, such as a bolt and a spring 33 as hereinbefore described in reference to FIG. 1A (see Detail 1).

FIG. 3B is a cross-section detail View 3-3 of the plate from FIG. 3A.

A preferred network of bars, displayed in detail in FIGS. 3G to 3N has an advantage over a network of bars with radial and tangential components because a tangential heat path only dissipates heat without radially conducting it. Due to the practically zero temperature differences between the two ends of any tangentially disposed bar, the heat flow within the bar is minimal and depends only on the small amount of heat dissipated from the bar. When considering the small amount of heat flowing through each tangentially disposed bar, even the minimally sized bar that manufacturing technology enables, has an oversized cross-section, which reduces the efficiency of the heat-sink heat dissipation capacity per unit weight.

Low weight and low center of gravity are important targets in selecting an optimal heat-sink due to the desired small dynamic and static moments and forces applied by the heat-sink on the PCB and processor's socket.

By utilizing perforated plates several advantages can be observed: (1) A small footprint, low weight core, replaces the solid base of common finned heat-sinks, which serves only as a heat spreader to the fins while practically not participating in heat dissipation to the air. (2) The bars serve simultaneously as horizontal (X, Y directions) heat spreaders and heat dissipaters to the air. (3) The parallel airflow within the perforations—enabled by stacking the perforated plates with their perforations aligned through the stacked plates—when in association with a counter-flow of heat and air, ensures a positive temperature difference between the air and the fins along the air-pass, while in most heat-sinks the air warmed by the internal hot fins flows over the external cooler fins reducing the temperature differences and the heat dissipation capacity.

The footprint area for the perforations can be sized in any pattern to optimize the airflow in association with the air-moving means. Such optimization criteria can be either uniform velocity in all the air passages formed by the stacked perforations, or uniform exhaust air temperature from each such air passage, or uniform heat dissipation per unit area, and the like.

In a preferred embodiment of the invention, the plurality of air passages sustain a uniform mean-velocity vector of air flowing along the whole length of each individual passage of the plurality of passages within the heat-conducting elements prior to the air being exhausted from the heat sink. The overall goal is to reduce the thermal resistance of the heat-sink per specified geometrical volume, weight, center of gravity height, noise emission, power consumption, and the like while each criteria is weighted differently by different users and in different applications.

As described below, when press-fitting the plates on a heat-pipe serving as the axial heat-conducting core or embedding a heat-pipe within a hollow solid core, the footprint of the core can be reduced and the fin area increased, which leads to a reduction in thermal resistance of the heat-sink.

FIG. 3C illustrates a perforated plate 114 with its center 116 specially perforated to enable a melted heat conducting agent to be pored into and fill in the perforations, turning the central core 116, after the agent solidifies, into a solid monolithic heat-conducting block.

FIG. 3D illustrates a perforated/indented plate 110 with an uncut central section 112, adapting at least the central sections of the stacked plates to be fused into a solid monolithic thermally conducting core with good thermal conductivity in the axial direction (“Z” direction). Fusion can be accomplished by combining pressure and temperature that plastically fuse together the plates or by applying a cladding with a melting temperature lower than the substrate plate, which upon heating to its melting point the melted cladding layer thermally connect the surfaces in contact and accordingly also the substrate plates, which after solidifying the thermal and physical contact turns permanent turning the individually stacked plates into a solid heat

FIG. 3E is a top view of the face of a section of a plate 120 with indentations 122 of elliptical-airfoil shape populating its face and supported by non-indented ribs 106. The direction of the inhaled airflow is marked by arrows A and the exhausted air indicated by arrows B.

FIG. 3F is a cross-section View 4-4 from FIG. 3E of stacked, discrete indented plates. One face is shown populated with protruding indentations 122 forcing the air to change the flow direction while crossing the plate 150. This disturbs to some extent the boundary layer which increases the heat transfer coefficient from the plates and indentations to the air at the expense of increased pressure losses which the air-moving device provides. The non-indented surfaces 130 are in contact with the top end 134 of the indentations 140.

The area enclosed by walls 138 and 140 and the plane 130 defines the air passages 136. Although not essential for the operation of a heat-sink composed of indented plates, the plates can be thermally fused when appropriate pressure and temperature are applied preferably with cladding material being applied as described before thermally fusing the plates into solid perforated heat conducting block with improved thermal conductivity and lower thermal resistance.

FIGS. 3G to 3L are cross-section views of various configurations of flow-through, stacked, folded, and indented plates and strips in accordance with the principles of the present invention.

FIG. 3G is a cross-section view of an indented plate configured with folded strips generally indicated by arrow 150, which is periodically identically indented on different sides with the length of the non-indented sections 152 identical to that of the indented sections 152, with each indented section oppositely folded. The bent section 156 is suitably sized to enable the bending.

FIG. 3H is a cross-section view of perforated stacked plates 156 spaced apart by axial distance 158, with bars 162 and the perforations defined by two sections, a cylindrical section 164 with walls parallel to the symmetric axis (not shown) and a concentric conical section 166 as constitutes the perforation shape which formed during the hole-punching process to make the perforations. The punching pin enters the plate from the side of the cylindrical section 164 and leaves through the conical section 166.

With a suitable cone angle and spacing between the plates 156, air enters into the perforations according to arrows A and its envelope will spread in accordance with the slope of edge 172 whereupon when impinging with face 168, the air will whirlpool between the bar faces 168 and dissipate heat also from those sections of surfaces 168 and 170 which are in contact with the whirling air. This embodiment is associated with increased air pressure drop, which is supplied by a matching air-moving device.

Air can also flow opposite to the airflow direction shown in FIG. 3H, at a reduced pressure drop, similar to the airflow direction in respect to the direction of the perforation walls as explained below and illustrated in FIG. 3J.

FIG. 3I illustrates the plates from FIG. 3I with a tightly stacked configuration. The entering air (shown by arrows A) pass through conical perforations 166 and the air exits (arrow B) through air passage 164.

In FIG. 3J, the stacked, perforated plates are provided with perforations 170 and bars 172 which are also partially indented by cone indentations 174, with the height of the indentations above the surface of the plates defining the width of the space for airflow. The plates 156 are stacked slightly apart due to the protruding cone indentations 174. The larger radius of the cone indentations 174 ensures that despite misalignments occurring due to manufacturing and assembly tolerances, the perforations 170 in adjacent plates will overlap. Air is preferably flowing in accordance with the arrows A for the intake air and B for the exhaust air.

FIG. 3K is a cross-section of another configuration of stacked plates in accordance with the principles of the invention. Entering air (arrows A) is shown to flow opposite to the airflow direction in FIG. 3J, and at a reduced pressure drop, similar to the airflow direction in respect to the direction of the oblique perforations walls 172 as in FIG. 3I

The perforated, stacked plates 156 of FIG. 3K, in another embodiment of the invention, are populated by two types of perforations 180 and 181, with the perforations 181 identical to those described hereinbefore while the conical walls of perforations 180 protrude out of the plate surface 183. Perforations 180 are stacked one inside the other and accordingly define a gap 184 between the plates. Grooves 185 on the conical wall of perforations 180 are a manufacturing option. The gap between the plates 184 is defined by the plate thickness and cone angle of the conical perforated and indented holes 180.

FIG. 3L is another configuration for stacked perforated plates with the airflow flowing through staggered, trapezoidal perforations as indicated by arrows A/B.

FIGS. 3M is a top, cross-section view of airflow across a perforated plate provided with sections of perforations 192 and ribs 194 that enable multi-directional air flow, as indicated by the arrows, away from a central heat-generating core 190.

FIG. 3N is a detailed view of another embodiment of a section of a perforated plate provided with rhomboidal perforations 200. The rhomboidal perforations 200 provide for reduction in the passing noise from the blades (not shown) of an air-moving means in a cooling device (not shown) rotating radially above perforations 200.

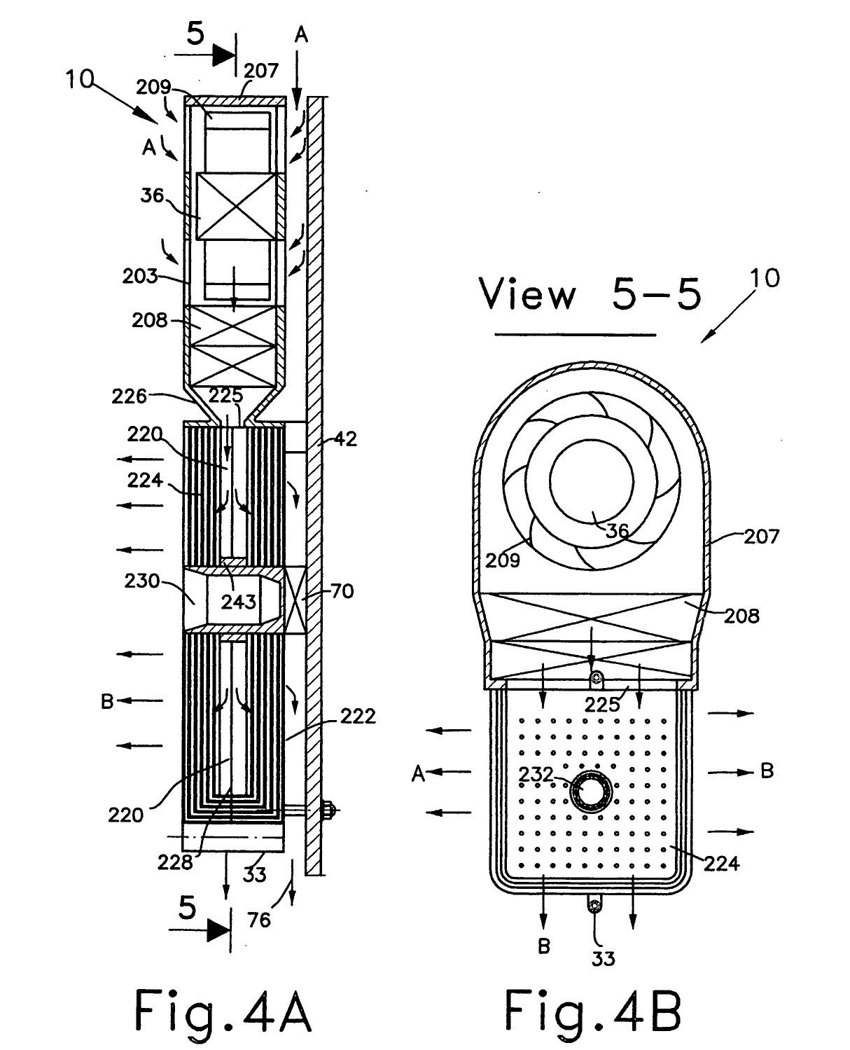

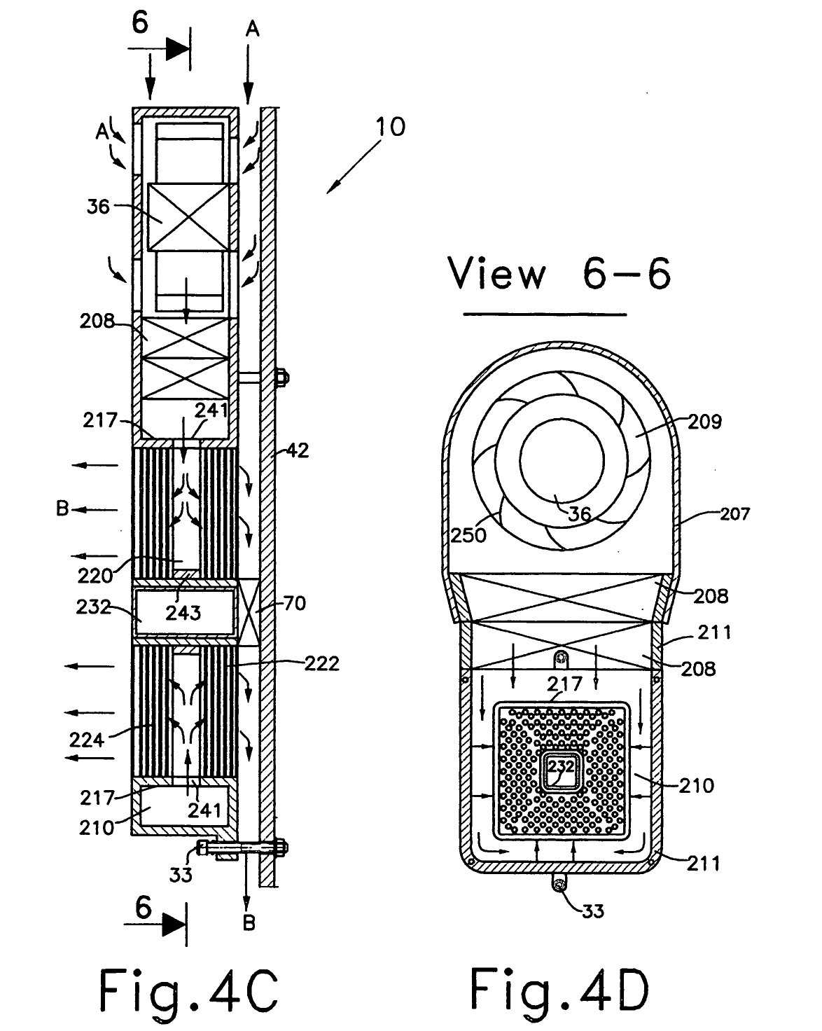

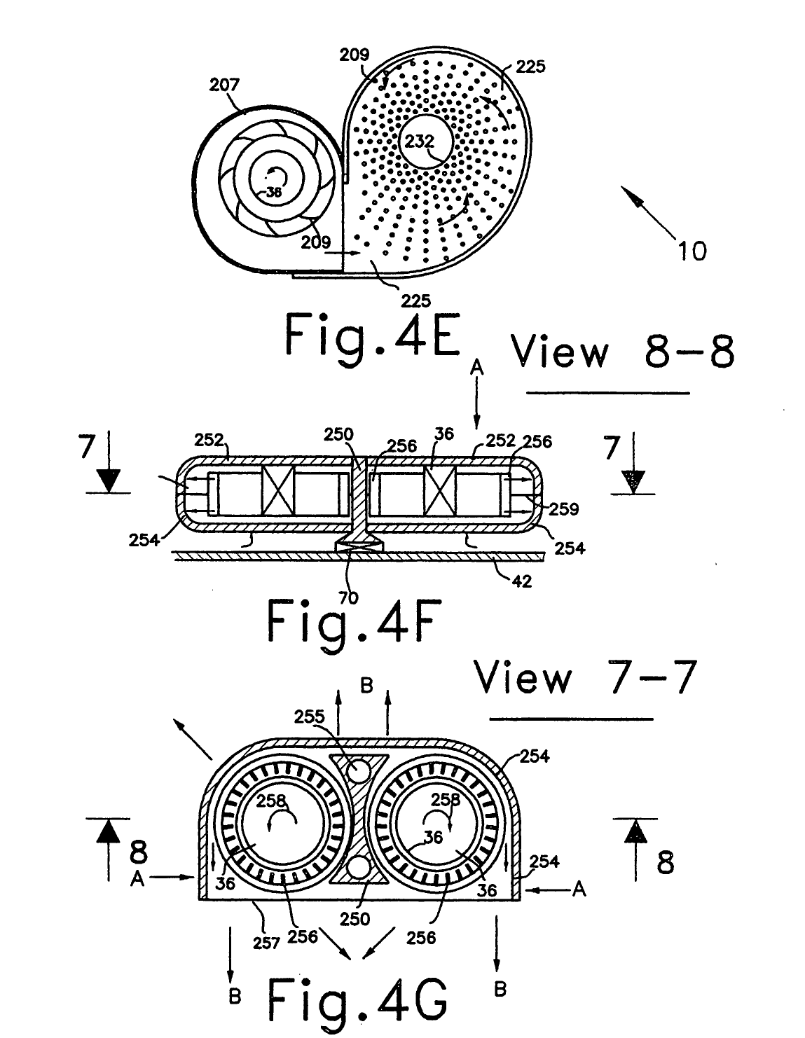

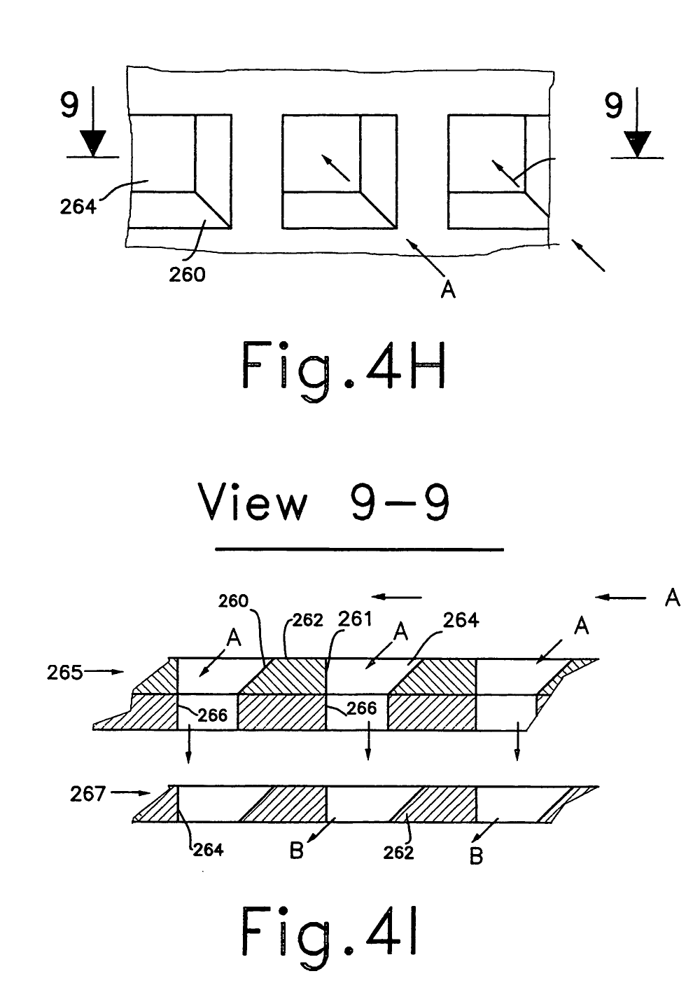

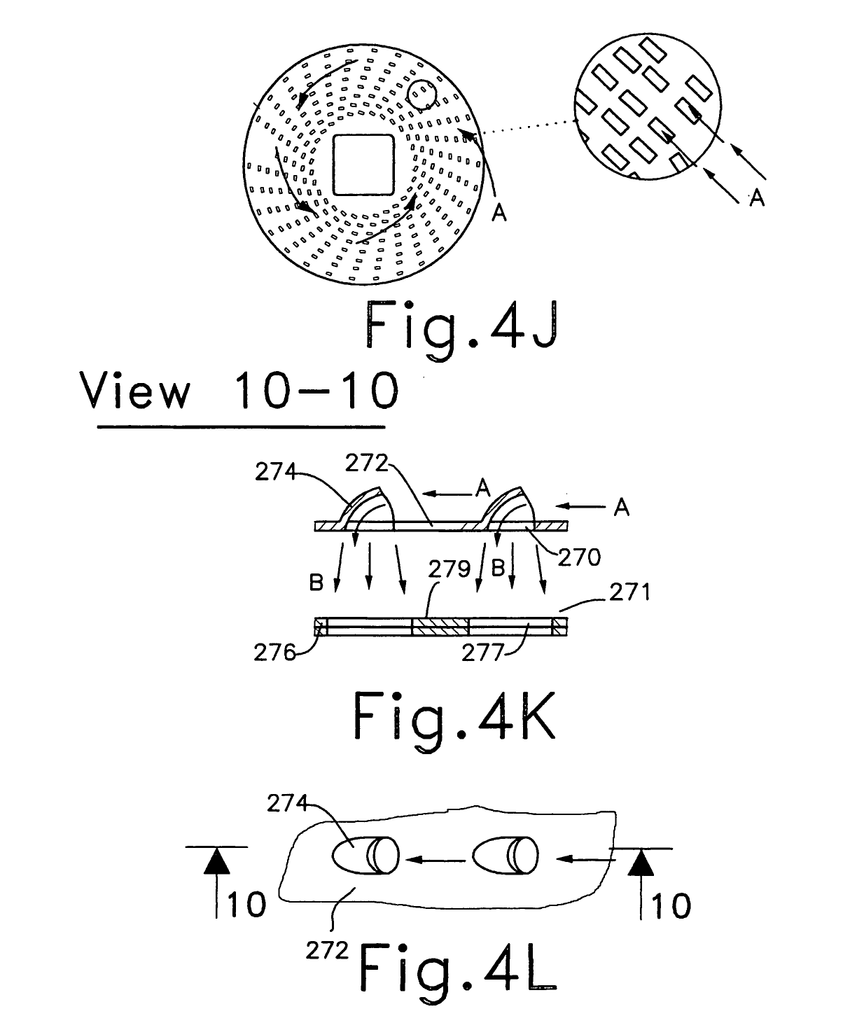

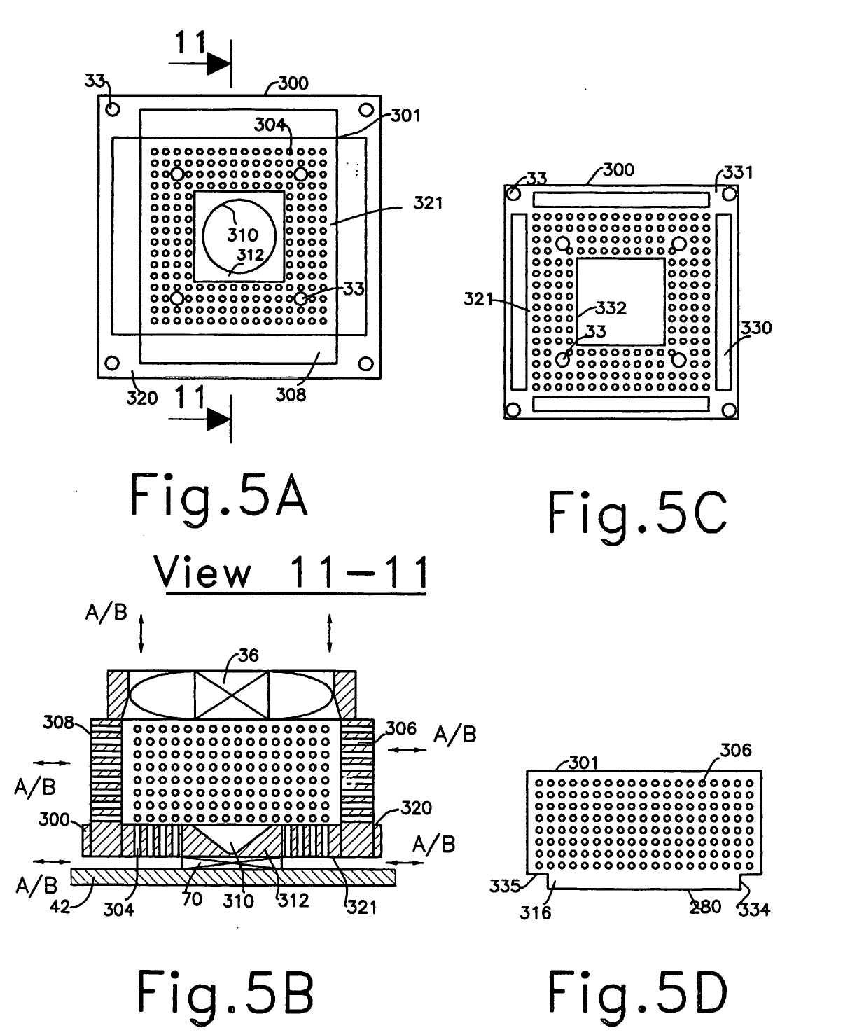

FIGS. 4A to 4G illustrate another preferred embodiment of the invention provided with side-mounted and internally mounted air-moving means.

With reference to FIGS. 4A and 4B, a cooling device 10 with an air-moving means, in this case a side-mounted blower defined by its motor 36, peripheral envelope 207, air inlets 203, and blades 209, delivers air from the side opening 225 toward the top of the heat-sink plates 224 where the directed air crosses the stacked perforated plates 224 and is exhausted as indicated by arrows B. Indrawn air is indicated by arrows A.

Incoming air (arrow A) enters the heat sink 10 and is forced by the blower 36 to pass through an optional filter 208, or else directly passed through a converging neck 225 into a circumferential plenum 210, from where the air continues to flow to the top plenum 220 and from thence into the perforated plate fins 224, finally being exhaled as indicated by arrows B.

The central core 230 is a solid block press fit mounted in the hole provided in the center of the plates 224, which makes indirect thermal contact with the heat-generating component 70. The heat-sink is attached to a mounting surface 42, such as a PCB via attachment means 33 (indicated as holes in mounting flanges in FIG. 4B), such as screws. The fins 224 are press fit against the internal side of frame 219.

FIG. 4B is a cross-section View 5-5 of the cooling device from FIG. 4A.

The heat-sink in this preferred embodiment of the invention is composed of two bent, stacked, perforated plates, sections 222 and 224 press-mounted on the bored core 230, forming a circumferential sealed contact along plane 228. The bored core 230 is an option, which can be used also with all other relevant embodiments of the invention, adapting the axially reducing wall thickness to the axially reducing heat flux, keeping heat flux constant, thus reducing the overall weight of the heat-sink.

This embodiment of the invention presents a longer thermal path and higher thermal resistance for the heat flowing from the core 230 to the fins 224/222 and provides for lower airflow resistance as compared to the embodiment from FIG. 1A, due to the smaller thickness of each section and the larger airflow area provided by the larger surface of the plates.

FIG. 4C illustrates a cooling device marked generally as 10 with the air delivered peripherally from the side mounted blower 36, as described hereinbefore in reference to FIG. 4A, and through the circumferential opening gap 241 into the central space between two sections 224/222 of the heat-sink as describe above. The core 232 is a heat pipe, which can be applied also to other relevant embodiments of the invention. A spacer ring 243 ensures the proper gap width between the two groups of plates 224/222.

FIG. 4D is a top cross-section View 6-6 from FIG. 4C. FIG. 4D displays the airflow pattern (arrows) from the blower through the perforated plates and out of the cooling device.

FIG. 4E is a top, cross-section view of an embodiment of the invention provided with a side-mounted blower 36 with a closed wall 207 directing the air A through an opening in wall 207 into a curved section of heat-sink 10 fitted with perforated, stacked plates 225 enclosed by walls 209. The air (arrows) circulates around central core 232 and is forced out through the perforations in plates 225.

FIGS. 4F and 4G are side (View 8-8) and top (View 7-7) cross-sections respectively, of an embodiment of the invention provided with twin blowers disposed internally within a space confined between the walls of a heat-sink.

FIG. 4H and 4I are a top view and a cross-section View 9-9, respectively, displaying a forced airflow pattern through stacked perforated plates in accordance with the principles of the invention.

FIG. 4E illustrates a top view of a cross-section of an embodiment of a blower and a curved heat-sink which can be adapted to the any of the embodiments in FIG. 4A to 4C. The air enters the heat-sink in a smooth flow and the heat-sink converges downstream in accordance with the reducing volume of flowing air.

FIGS. 4F and 4G illustrate two views of cross-sections of a cooling device with twin blowers disposed within the heat-sink.

The cooling device marked generally as 10 is composed of two asymmetrically deep drawn perforated plates 252 and 254 mounted on a common core 250, attached along the plane 259, in a manner that forms a plenum between the plates with one of the plenum sides 257 is open. Twin motorized blowers, indicated by their motors 36 and blades 256, are mounted within the plenum and in operation, rotate in opposing directions as indicated by the arrows. The core 250 is connected to a heat-generating component 70 mounted on PCB 42. As an option, heat pipes 255 are embedded in the core 250. The impellers rotate in opposite direction. The air indicated by arrows A and B is either indrawn or exhausted through the perforations. In accordance with the pressure differences on each section of the plate caused by the suction, venturi and impingement effects in respect to each of the sections.

FIGS. 4H to 4L illustrate various types of air-directing means for gradually changing the direction of airflow in preferred embodiments of the invention in accordance with the principles thereof.

FIG. 4H and 4I are a top view and a cross-section View 9-9, respectively, of through perforations.

In FIGS. 4H and 4I the perforations 264 are stamped to change at least part of the perforations walls from walls 261 vertical to the plates surface 262 to oblique walls 260. The lower plates are not stamped with the walls of perforations 266 vertical to the plate surface. The lower plate is placed as the upper plate. It can be noticed that the flow direction of the entering air A is changed more gradually as compared to the change brought about by vertical walls. The exhausted air is directed diagonally as is employed for example in FIGS. 4A to 4C in order to direct the expelled air away from the air indrawn by the blower.

FIG. 4J is a top view of a circular perforated plate with a magnified detail of the perforations providing air-directing means in accordance with the principles of the invention. Note that the direction of the longitudinal axes of the perforations are at any point parallel to the tangent to the spiraling airflow direction marked A.

FIGS. 4K and 4L are a side cross-section View 10-10 and a top view, respectively, of protrusions providing air-directing means in accordance with the principles of the invention.

Material within the footprints of the perforations 270 is partially circumferentially cut and is pushed out of the plate surface 272 to protrude above plate surface 272, forming air-directing vanes 274. These vanes 274 direct the air (arrows A) flowing across and parallel to plate surface 272 to smoothly and gradually, and with less turbulence, change its direction so that the airflow is in the direction of exhaled airflow, marked by arrows B.

The exhaust air B is directed to pass directly and efficiently through the air passages 277 formed in the lower stacked plates 271 without significant loss of air momentum from inadvertently impinging on perforation-free surfaces 279 where it could significantly affect the performance of the heat-sink as can occur with plates populated by perforations in a configuration with their walls vertical to the plate face.

The cross-section of vans 274 can be curved in accordance with the shape of the stamping tool. This configuration can be applied to all embodiments where the airflow is substantially parallel to the face of the plates or to sections thereof in order to direct the airflow to be exhaled either oblique to the plate face surface as described before or vertically and directly into the lower plate perforations 277 as shown is FIG. 4K.

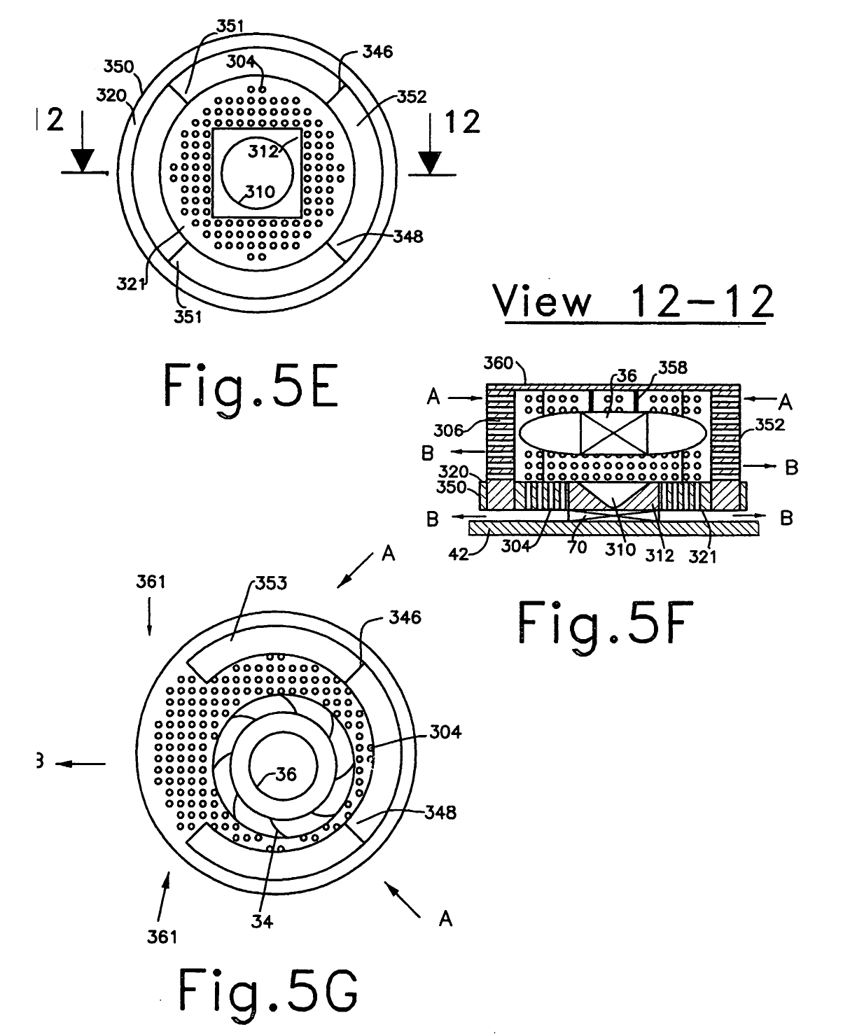

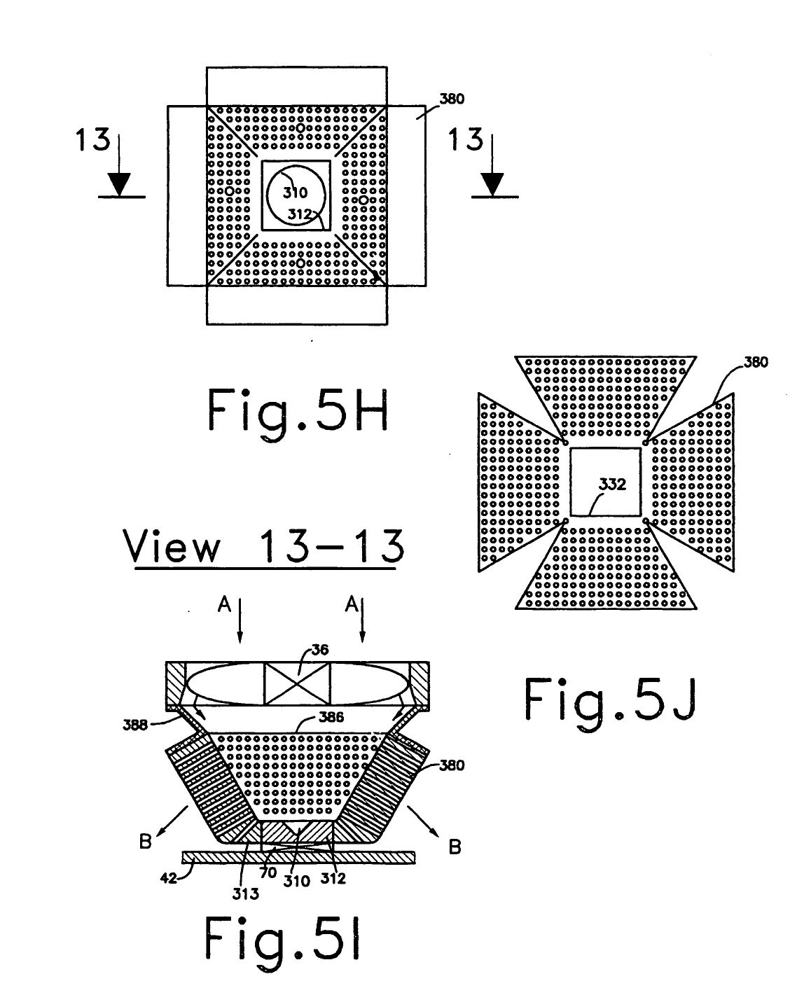

FIGS. 5A to 5J illustrate yet other configurations of an embodiment of the invention comprising perforated, cup-shaped plates;

FIGS. 5A and 5B are a top view and a side cross-section view, respectively, of a square, cup-shaped heat-sink with a top-mounted axial fan. For clarity, the top-mounted axial fan is only shown in View 11-11 of FIG. 5B.

As is known to those skilled in the art, the embodiment of the invention shown in FIGS. 5A and 5B, wherein an axial fan is the air-moving means to provide the active air cooling, can also be activated by a blower and vice versa, although only a single type of air mover is displayed, without limiting the relevant embodiment of the invention to a specific type of air-moving means.

FIG. 5C is a top view of the base plate of the embodiments from FIGS. 5A and 5B provided with the through-openings for insertion and swaging of the walls and the core.

FIG. 5D is a view of a perforated wall plate before insertion into the openings provided in the base-plate of FIG. 5C.

With reference now to details shown in FIGS. 5A to 5D, a perforated base 300 composed of stacked plates with perforations 304 is thermally and mechanically supported on swaged vertical walls 308 composed also from stacked perforated plates with perforations as can be seen in FIG. 5D, which together with the base 300 define a closed cup-shaped heat-sink wherein the wall sides seal the cup along lines 301. Opening 332 in FIG. 5C enables press-fitting core 312 as shown in FIGS. 5A and 5B with central bore 310, as described before. Openings 330 in FIG. 5C are matched with the inserted section 316 of wall 308 to form a good thermal contact between the base and the walls after swaging. The section 316 is preferably pre-pressed and thermally fused before insertion into the base 300 to ensure a good thermal contact between the stacked wall and base plates.

The comers of the base 300 support an attachment means 33, such as a bolts and spring arrangement, which are generally used to connect a heat-sink to a mounting surface, such as PCB 42 while forming a controlled contact pressure between the heat-generating component 70 and the heat-sink, as described hereinbefore. Alternately, with a top-mounted air-moving means 36, as shown in FIG. 5B, the attachment means 33 can be mounted through the internally disposed holes 33. The narrow flange section 320 on the base side external in respect to the walls 308 and the perforation-free section 321 on the base 300, internal in respect to the walls 308, serve as the swaging area, wherein applied axial pressure plastically deforms sections 320 and 321 pushing them downward and sidewise toward the sides of section 316 of the walls 308 to form a continuous thermal contact between the plates composing the base 300 and the walls 308.

The height 334 of the insertion 316 is preferably equal to the axial thickness of base 300 while the length of section 334 is minimized. The axial fan defined by its motor 36 displayed in FIG. 5B provides the cooling air. The internal periphery of the walls 316 is matched with the air outlet opening of the fan to ensure free airflow from the fan into the space confined between the wall 316 and the base 300.

The holes 33 for attachment means, in the preferred embodiment of the invention, comprise connecting bolts/springs which can be disposed externally or internally. A small external flange section 320 on the external side of base 300 respective to the walls 316 and perforation-free section 321 on the base 300 on the internal side of the walls 316 serves as the swaging area wherein applied axial pressure plastically and axially deforms sections 320 and 321, pushing them toward the sides of wall section 316 to form a continuous thermal contact from all the plates composing the base 300 to all the plates composing the walls 316.

The height 334 of the insertion 316 is preferably equal to the axial thickness of base 300. The solid section 331 between openings 330 connects the external parts of the base 300 to the internal section and are sized accordingly with the intention to minimize their size and the size of their counter-section 335 of the walls 316 to maximize the contact area between the base 300 and the walls 316. Axial blower 36 is sized to match the internal circumference of the heat-sink and provides the cooling air

With the air exhausted at high velocity from the fan into the relatively large internal space of the heat-sink, air velocity will be reduced and pressure increased subjecting all perforations to nearly identical pressure differences. By suitably sizing the perforations, airflow into the perforations is provided at a nearly uniform pressure difference. With perforations properly sized, the temperature of exhaled air can be kept uniform, or the heat dissipated per perforation area can be kept uniform, or any other optimization of operation criteria can be easily controlled. Airflow direction can be reversed with the air inhaled into the internal space and exhaled axially out of the space by the motorized impeller. The drawback of this option is the presence of heated air flowing onto the motor bearings, which reduces their life span substantially as compared to the previous arrangement.

FIG. 5E is a top view of a circular, cup-shaped embodiment of the invention.

The cup-shaped heat-sink of FIG. 5E is provided with a circular base 350 and circular walls 352. An axial motorized impeller defined by its motor 36 is mounted within the space confined by the walls 352 and the base 350, supported on supports 358, which are connected to a cover 360. The opening to the confined space is wholly covered by cover 360. The broken lines 351 indicate the ends of the circular openings in the base 350 where the walls 352 are inserted and swaged to base 350 to form the desired thermal contact.

With an air-tight cover 360, air is inhaled from the upper section of the wall in accordance with arrows A and expelled through the lower part of the walls and the perforated section of the base in accordance with arrows B. Employing a solid air-tight cover 360 reduces the noise emission by the motorized impeller. The reduced noise enables use of a higher-speed and accordingly, generates a higher pressure which enables deployment of thicker walls and base, reducing the thermal resistance of the heat-sink due to higher energy consumption of the motorized impeller 36.

FIG. 5F is a side, cross-section View 12-12 of the circular cup-shaped cooling device from FIG. 5E, shown with an air-moving means comprising an internally disposed axial fan.

The air-moving means, defined by and comprising an internally mounted axial motorized fan 36, is supported on supports 358 and provided with a closed cover 360. All other components composing the heat-sink in FIG. 5F are identical to those in FIGS. 5A to 5E.

Alternatively, when provided with a perforated cover (not shown) external and cooler air is also inhaled into the confined space mixing with the inhaled warm air at proportion dictated by the proportion in airflow resistance between the perforations in the cover and air-inlet perforations in the upper section of the walls. Accordingly the cooler air reduces the temperature of the air exhaled by the blades 34 toward the lower side of the walls 353 and the base and improve the heat-dissipating capacity of the heat-sink.

FIG. 5G is a top, cross-section view of a circular, cup-shaped cooling device with an open-wall section indicated by arrows 361 and with an internally disposed radial blower 36. The circular, cup-shaped heat-sink is provided with an opening 361 in the wall 353 which enables the motorized radial blower, defined by its motor 36 and blades 34, to expel the incoming air (arrow A) at a specific direction marked by arrows B.

Accordingly, air is inhaled or expelled through the perforations 304 in accordance with the pressure differences on the various sections of the perforated plates as created by the blower-generated suction, the venturi effect of the air flowing parallel to the relevant sections of the plates with perforations 304, and air impingement upon relevant sections of the plates.

With a properly perforated cover (not shown), small amounts of cool ambient air enters into the confined space and become mixed with the air moved by the blower in various proportions according to the geometry and position of the blower 36 in respect to the heat-sink, as described before.

FIGS. 5H and 5I are a top view and a cross-section View 13-13, respectively, of another embodiment of the invention.

The wall-plates 380 are thermally attached to the base 313 by insertion of the wall-plates 380 into through-openings provided in the base-plate wherein they become mechanically and thermally fused, for example by swaging or press-fitting, with or without a fusing agent such as the cladding described hereinbefore, thus forming a continuous thermal path from all the sections composing the base 313 to all the sections composing the walls 380.

FIG. 5J is a top view of stacked perforated plates 380 cut into a cross-like shape which enables bending them into the cup-like embodiment of the heat-sink displayed in cross-sectional View 13-13 in FIG. 51 and in top view in FIG. 5H, with upwardly inclined walls 380 which are monolithic thermal and physical extensions of base 313. The air outlet from the top-mounted axial fan, defined by its motor 36, is symmetrically larger than that of the heat-sink air opening, which is defined by the internal upper perimeter of the walls 380. The air directing plates 388 bridge the differences in sizes connecting the fan 36 to the heat-sink while directing the expelled air (shown by arrows) from fan 36 to change its flow direction gradually while flowing into the space confined internally within the heat-sink.

FIG. 5J is a top view of the cutting pattern for a flat, stackable plate which enables bending the plate into the cup shape shown in FIGS. 5H and 5I.

Due to the bending radius of each plate in respect to its adjacent one, relative radial staggering occurs of the bars of plate material defining the patterned arrangement of perforations in adjacent plates. The perforations are therefore preferably rectangular with the shorter and thinner bars in the tangential direction and the longer and thicker bars in the radial direction in a manner which provides sufficient airflow cross-section area despite the reduction of the cross-section by the staggered bars which overlap the holes in adjacent plates.

Although not shown, the converging air-directing means can be applied to other embodiments to connect a fan to a heat-sink wherein the footprint of the air inlet/outlet of the fan is larger then the footprint of the air outlet/inlet to the heat-sink, respectively.

It should be clear to those skilled in the art, that the embodiments in FIGS. 5A to 5J; as well as other embodiments hereinafter described, where only a single type of air-moving means is displayed, be it an axial fan or a radial blower or just radial or axial motorized impellers without the external frame, the embodiments can be activated by any of the two types of air-moving means, therefore the limited descriptions are not limiting the relevant embodiments to become associated only with a specific type of air-moving means.

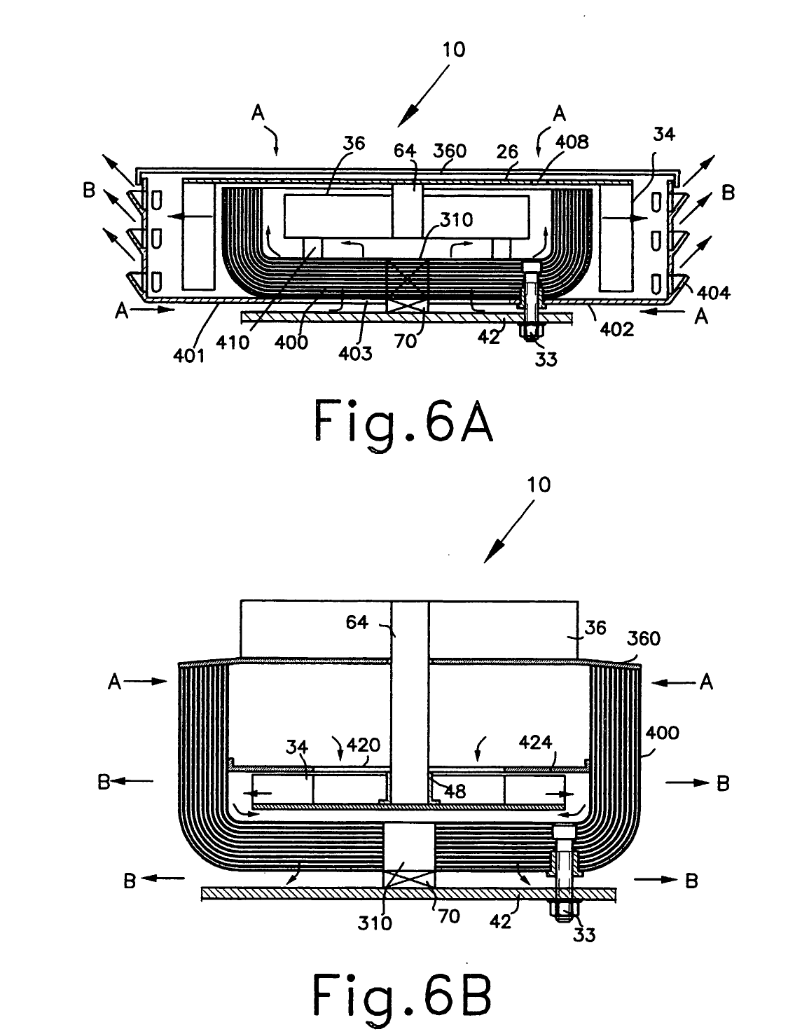

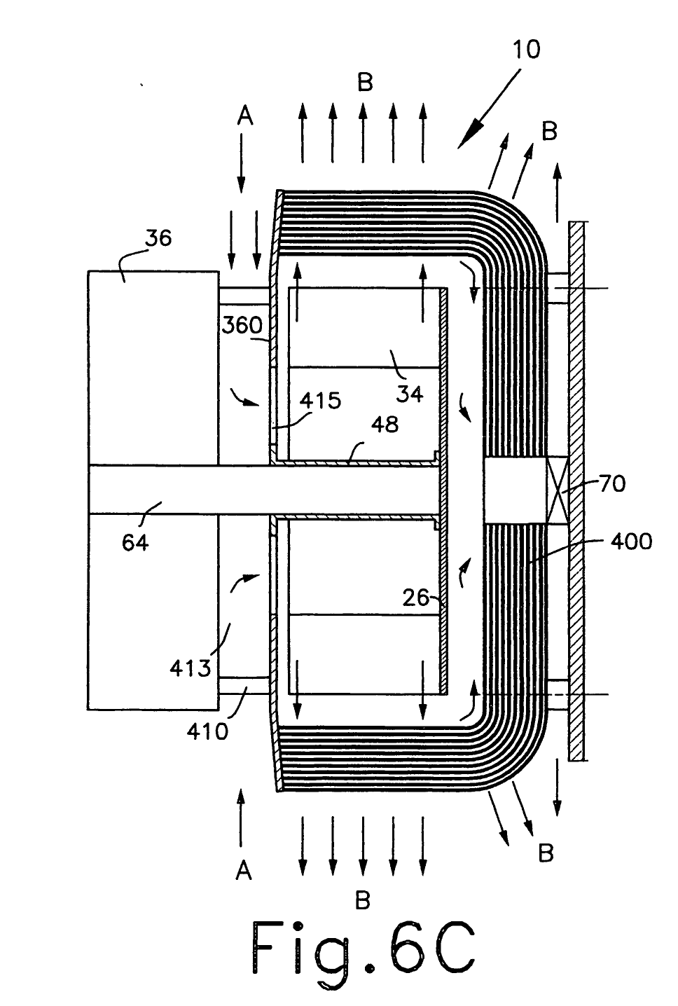

FIGS. 6A to 6C illustrate still other embodiments of the invention comprising deep-drawn perforated plates shaped as saucers with their walls monolithic extensions of their bases.

The embodiments of FIG. 6 are similar to those in FIG. 5, with the difference that instead of swaging-together separated plates into a closed, cup-shaped heat-sink, flat stacked plates are deep-drawn formed into cup-like shapes, with the walls forming monolithic and continuous physical and thermal extension of the bases.

FIG. 6A is a side cross-section view of an embodiment of the invention with an internally disposed motor and externally disposed radial blades.

The internally disposed axial fan is defined by motor 36 and externally disposed radial blades 34, wherein stacked perforated plates 400 are deep-drawn into a cup or saucer-like shape. The lowest plate 402 extends radially and axially to form a larger saucer-shaped envelope. A radial blower motor 36 is supported on supports 410 while connected by hub 64 to impeller 26 and blades 34. A solid cover 360 provides air-tight sealing on the fins-free opening side of the saucer-shaped plate 402. When the blades 34 are rotated by action of motor 36, air (shown by arrows A) is inhaled through the perforated base 401 into the internal space confined by the bent plates 400 and air is exhaled (arrows B) from the internally confined space through the perforated walls 400 formed by the upward extension of the plates. Air-directing openings 404 direct the heated exhaled air to flow in an upward path (arrows B) away from the cooler inhaled air A. Operationally, this embodiment of the invention is identical to the embodiments illustrated and described in relation to FIG. 5.

With a perforated cover 360, or just a finger guard as described before, associated with a slotted impeller (as described in FIG. 2B), external cooler air (arrows A) is also inhaled into the confined space in proportion to the hot air inhaled through the base 401, as dictated by the proportion in airflow-resistance offered by the cover 360 and slotted impeller 26 in respect to that offered by the perforated base 401. Accordingly, the cooler air, flowing through the open cover 360 and slotted impeller 26 is mixed at pre-designed proportion with the warmer air flowing from the base 401, and accordingly reduces the temperature of the air inhaled through the perforated walls 400 formed from the cup-shaped plates 410, which are cooler than the base 401 and benefit from the cooler air, by improving the thermal dissipating capacity of the relatively cooler walls 400.

FIG. 6B is a side cross-section of another embodiment of the invention with an internally disposed radial impeller and externally disposed motor, providing dual-pass airflow over the fins.

Perforated plates 400 are deep-drawn into a saucer-shape. A radial blower motor 36 is supported on cover 360 which is air-tight, sealing the fins-free top opening of the saucer-shaped heat-sink. Hub 64 is air-tight crossing the cover 360 while supporting the radial blades 34. When the blades 34 are rotated by the motor 36, air is inhaled according to arrows A through the perforations in the upper end section of the wall formed by the upward curving plates 400 and from thence through the opening 420 in the partition-plate 424 and into the blades 34 from where the air is then expelled (arrows B) through the perforated plates 400 forming the lower section of the walls. The noise-generating impeller is sealed and the motor 36 is disposed externally to the heat-sink, removed from and out of the way of the warm airflow.

With a perforated cover 360 (not shown) external cooler air is also inhaled into the confined space mixed with the warm air and exhaled through the lower part of the heat-sink, as described above.

FIG. 6C is a side, cross-section view of another embodiment of the invention provided with an internally disposed radial impeller and externally disposed motor, with single pass airflow over the fins.

In FIG. 6C, stacked perforated plates 400 are deep-drawn into a saucer-shape. A radial blower motor 36 is mounted on cover 360 externally to the space confined within the heat-sink 10 and supported by open supports 410. Shaft 64 and hub 48 cross the opening 415 in the cover 360 while supporting radial blades 34 mounted on impeller 26. When the motor 36 rotates the blades 34, air is inhaled (arrows A) through the space 413 between the bottom plane of motor 36 and the cove 360 and opening 415 in cover 360 and comes into contact with blades 34 from-where the air is expelled (arrows B) through the perforated base and walls comprising the saucer-shaped plates 400.

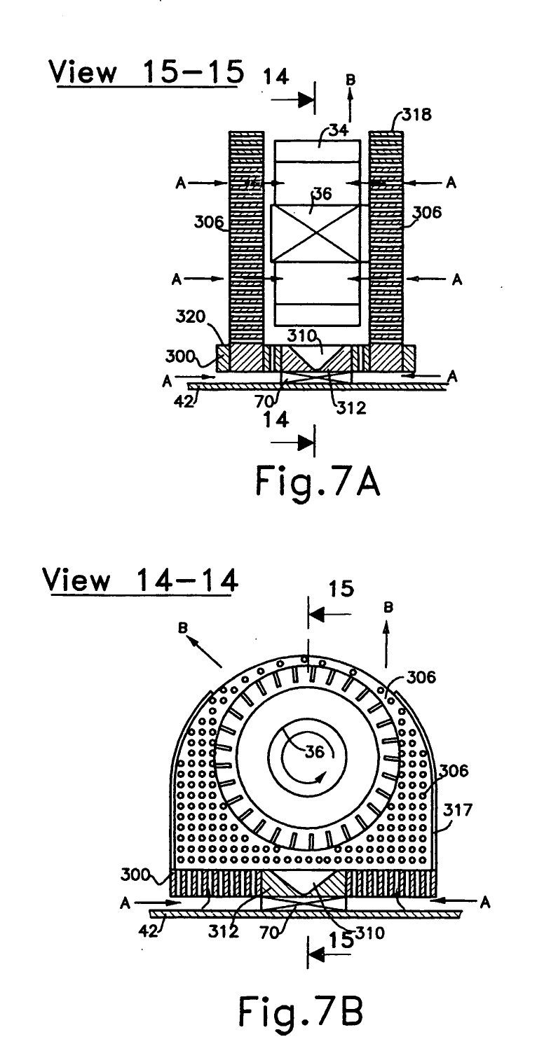

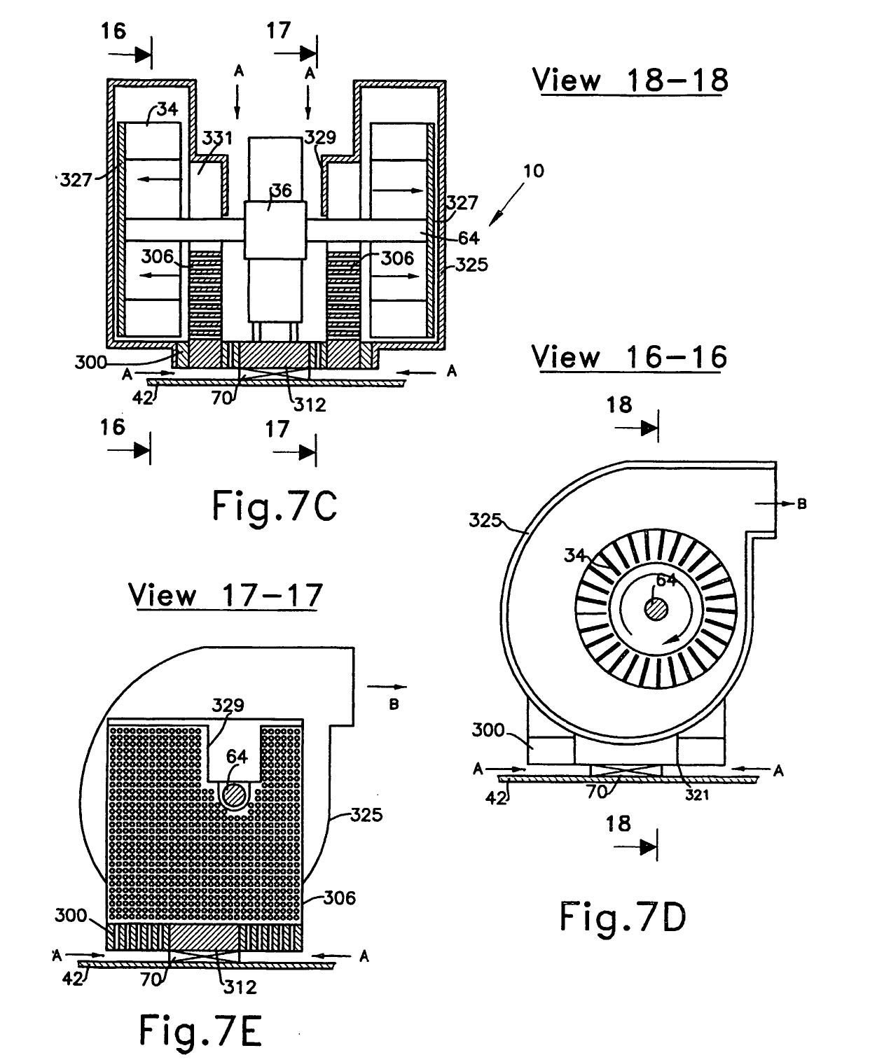

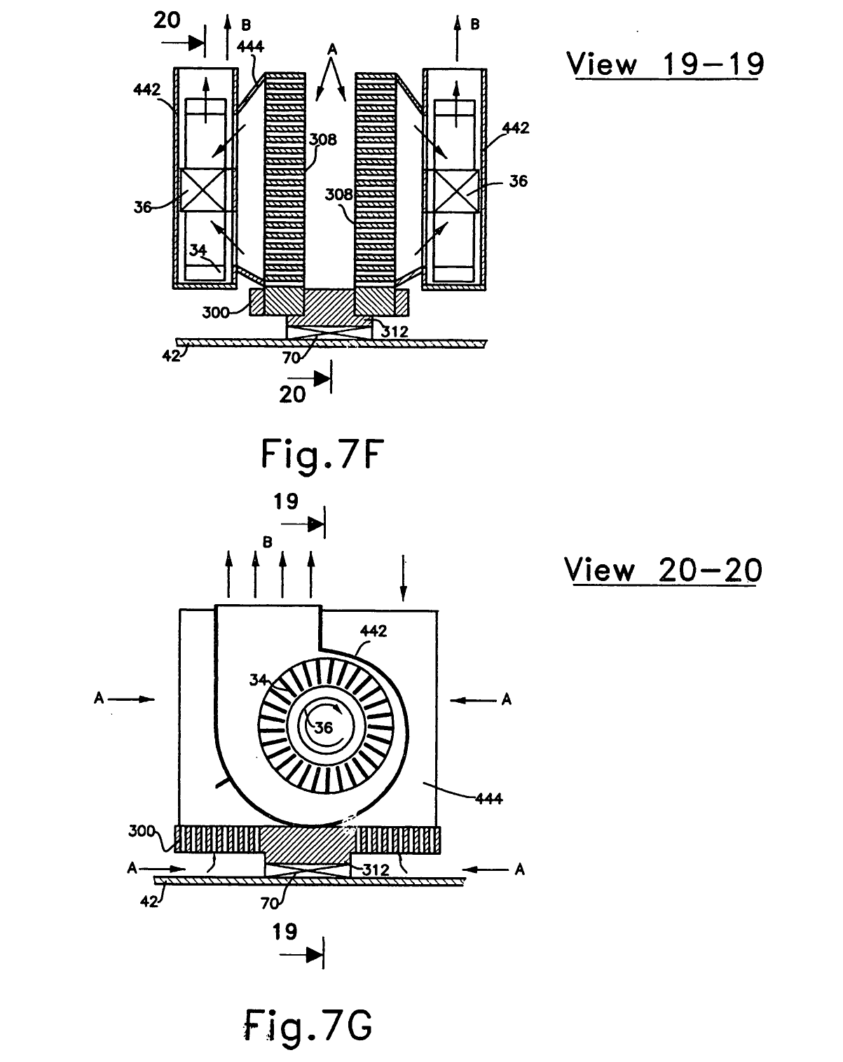

FIGS. 7A through 7G illustrate various further embodiments of the invention provided with open and closed double-walled heat-sinks.

FIGS. 7A and 7B are two, cross-section views, View 15-15, and View 14-14, respectively, of an embodiment of the invention comprising parallel-mounted, perforated-plate, swaged walls vertically protruding from a perforated base and a single, internally-mounted, radial motorized impeller.

The parallel, perforated walls 306 vertically protrude from a perforated base 300 and the cooling device is provided with a single, internally-mounted, radial, motorized impeller with dual air inlets, defined by its motor 36 and blades 34. The blades 34 are disposed within the space confined between the walls 306 and the base 300. The cooling device is shown with its base 312 in thermal contact with heat-generating component 70 mounted on a PCB 42.

Alternatively, the blades 34 may protrude beyond the walls 306 above a top line 318, while the majority of the blowers 36 and blades 34 are disposed within the space confined between the walls 306 and the base 300.

In FIG. 7B, which is a cross-section View 14-14 of FIG. 7A, air is inhaled (arrows A) in the upper portion of the dual-section cover 317 which can be of any shape and accordingly direct the air in different directions or cover 317 may be eliminated altogether and the air will then be exhaled in all directions.

Other features of the above-described cooling device are similar in function, if not in shape, to the earlier embodiments of the invention already described.

FIGS. 7C to 7E are cross-section views of another embodiment of the invention.

In FIG. 7C, the embodiment of the invention illustrated is also designated as View 18-18 from FIG. 7D. Two perforated plates 316 with perforations 306 with a single, internally disposed motor 36 rotate two externally disposed radial impellers 327 mounted on a common shaft 64. The impellers 327 support radial blades 34. Motor 36 is supported and attached to the base 312 of cooling device 10. Cover 325 directs the air (shown by arrows) in a specific direction indicated by arrow B in FIGS. 7D and 7E. Groove 331 enables insertion of the motor 36 with its protruding shaft 64 within the heat-sink 10. Plate 329 covers the groove 331 preventing air from bypassing the perforations via groove 331. The perforated plates 316 are secured in base 300.

Air is inhaled (arrows A) and exhaled (arrows B) as directed by the opening provided by cover 325 shown in View 16-16 in FIG. 7D. Cover 325 can be of any shape and accordingly direct the air in different directions. If necessary, cover 325 can also be eliminated causing the air to be exhaled from the blower in all directions.

FIG. 7E is a cross-section View 17-17 from FIG. 7C to show in detail the perforated plates 316 in relation to the blower cover 325 and the airflow exhaust (arrow B). The common shaft 64 of the motor 36 and impellers 327 is seen in cut-away.

FIGS. 7F and 7G are related cross-section views of yet another embodiment of the invention.

In FIG. 7F, a cross-section View 19-19 of FIG. 7G, two, vertically protruding perforated walls 308 extend from perforated base 300. Two, externally mounted radial blowers defined by their motors 36, blades 34, and envelope 442 are supported on the walls 308 by a pyramidal converging support 444 adapting the larger air outlet from the walls 308 to the smaller air inlet to the blower 36. The axial extension of the core tends to elevate the cooling device in respect of the PCB 42 to clear the space under the heat-sink for airflow and/or to allow for mounting higher components on PCB 42 under the heat-sink. Note that the covered blower 36 directs the exhaled air upwards.

An air filter (not shown) can be easily mounted within the internal space between the walls formed by the perforated plates 308. As is known to those skilled in the art, the shapes and sizes of the walls 306 described in association with FIG. 7 can vary and are adaptable in accordance with blower size and other geometrical and operational considerations. By suitably adapting the size of the blower and walls, the inhaling and exhaling air-directing means can be eliminated.

Accordingly, the air is inhaled and expelled in accordance with the optional air-directing means in the air inlets and outlets and the pressure differences on the various sections of the perforated plates 308 and the pins-free and cover-free opening between the plates 308. Such pressure differences are created by suction generated from blower 36, the venturi effect of the air flowing parallel to the relevant perforated plate sections, and air impingement with the relevant sections of the perforated base 300. Small amounts of cool ambient air may also be mixed with the warmed-up air moved by the blower 36, in various proportions according to the geometry and position of the blower 36 in respect to the heat-sink 10 and the sizes and shapes of various optional covers applied in association with a specific blower and walls.

FIG. 7G is a cross-section axial View 20-20 from FIG. 7F. The incoming air can enter the cooling device from several directions, including the perforated base 300 surrounding the to cool the heat-generating component 70, but the exhaust air, indicated by arrows B, only exits from top openings in walls 442 of the dual blowers 36.

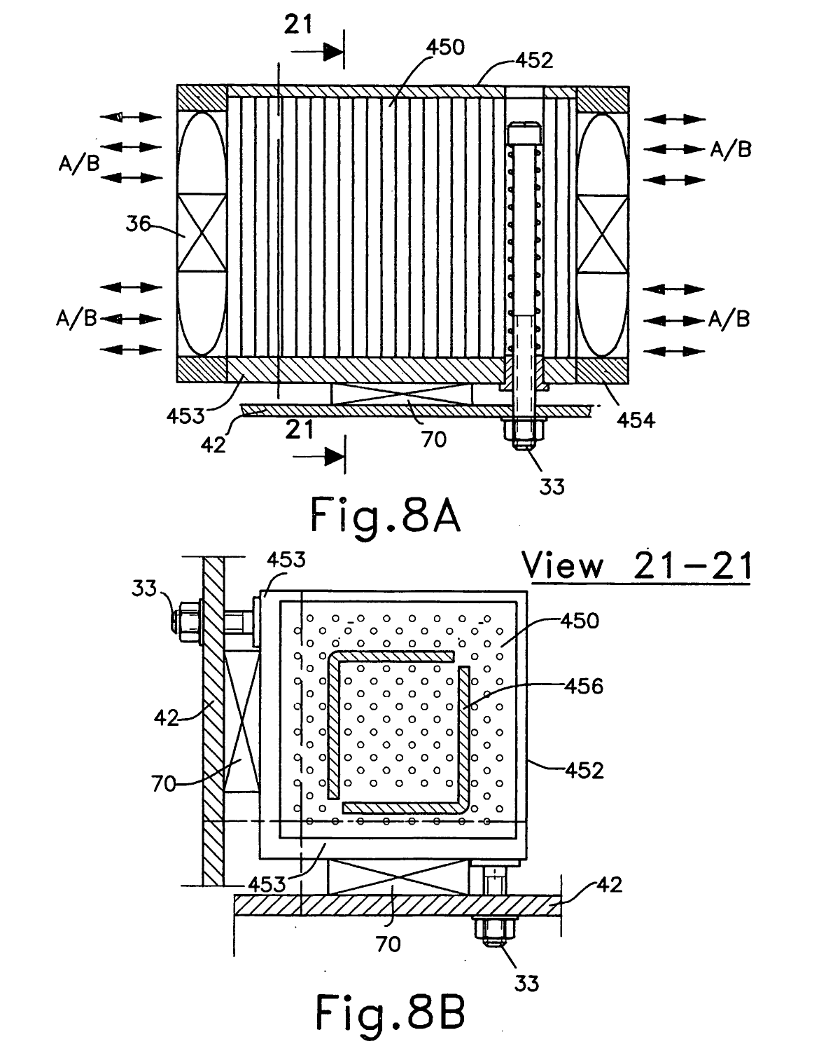

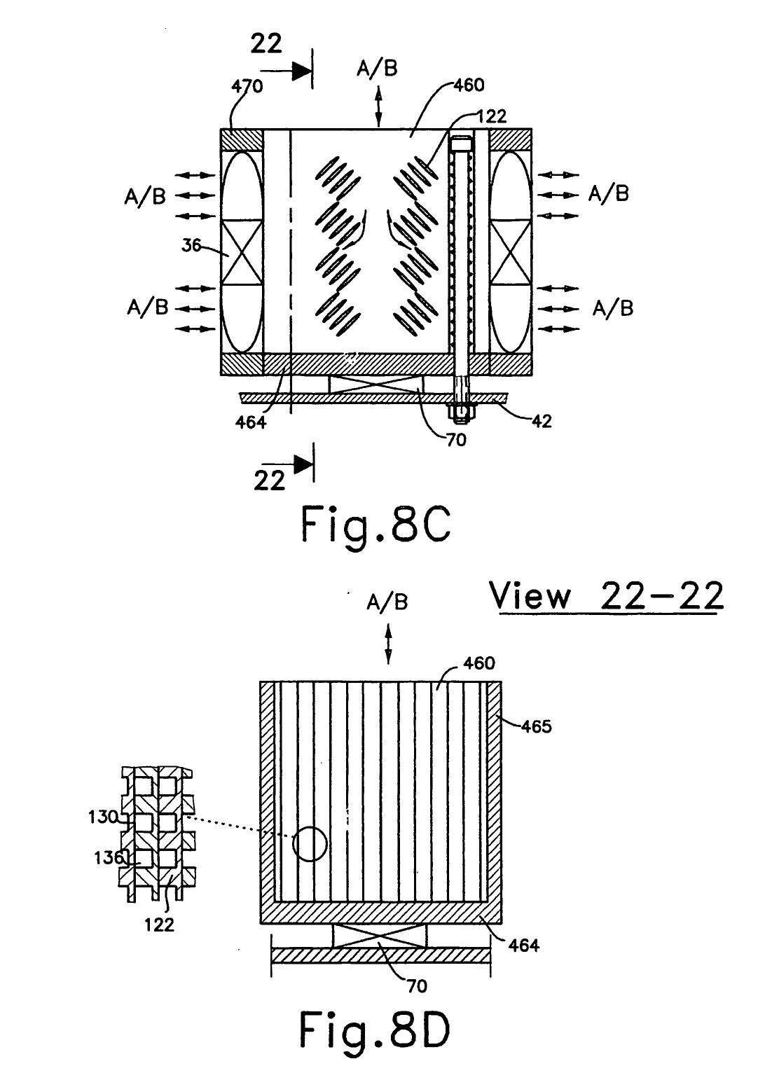

FIGS. 8A to 8D illustrate various configurations of a solid block heat-sink embodiment of the invention.

FIG. 8A is a side cross-section view of a heat-sink, formed in accordance with the principles of the invention, by tightly press-fitting perforated plates into an external closed envelope.

A heat-sink comprising a solid core press-fit into the heat-dissipating plates provided therein is one option to reach a thermal contact between all the plates and the heat-generating component, wherein, for example, thermally fusing the stacked plates as described before is another option to reach a thermal contact between all the plates and a heat-generating component. Additionally, a heat pipe may be embedded in the stacked plates and the solid core.

FIG. 8A illustrates an embodiment of the invention formed by thermally connecting perforated plates 450 to an external envelope 452 by press-fitting the plates inside the envelope 452. Two fans, defined by their motors 36 and frame 454, operate in line simultaneously, with one fan inhaling, while the other fan is exhaling the cooling air, as indicated by bi-directional arrows A/B.

The side of the envelope section 453, in contact with the heat-generating component 70, is thicker than the other sides not in contact with heat-generating devices, the thinner sides helping to reduce the heat-sink weight.

FIG. 8B is a cross-section View 21-21 of the embodiment of the invention from FIG. 8A, wherein a single cooling device is used to cool two, heat-generating components 70 on adjoining mounting surfaces 42. A heat pipe 456 is embedded in the finned area for improving the heat-dispersion quality of the heat-sink. The sections 453 in contact with the heat-generating components 70 are thicker than the sections 452, as noted above.

FIG. 8C is a side cross-section view of an embodiment of the invention formed by thermally fusing perforated plates into a solid heat-conducting block.

FIG. 8D is a cross-section View 22-22 of the cooling device in FIG. 8C.

FIGS. 8C and 8D illustrate an embodiment of the cooling device similar to that described in FIGS. 8A and 8B, formed by tightly press-fitting indented plates 460 covered with indentations 122 into an external, rigid enveloping section 464, thermally connecting the plates 460 and the enveloping section 464. The indentations 130 shown in the detail in FIG. 8D are also displayed in FIG. 3F.

Two fans defined by their motor 36 and frame 470 supply the cooling air (indicated by arrows A/B in FIG. 8C) to the heat-sink with both either simultaneously inhaling or exhaling the air. Indentations 122 are shown inclined, thus directing the air upward. With the longitudinal axes of the indentations 122 parallel to the rotating axes of the fans 36 as well as to base portion of enveloping section 464, and the top side covered as in FIGS. 8A and 8B, fans 36 operate in a similar fashion to the fan in the embodiment of the invention shown in FIGS. 8A and 8B. Airflow is bi-directional in accordance with arrows A/B.

Other configurations of the heat-sink of the invention may now be obvious to those skilled in the art, such as a heat-sink formed by tightly press-fitting indented plates into an external “U” shaped shell, and the like, and the preferred embodiments shown herein are not meant as a limitation, but only as illustrations of the inventive principle.

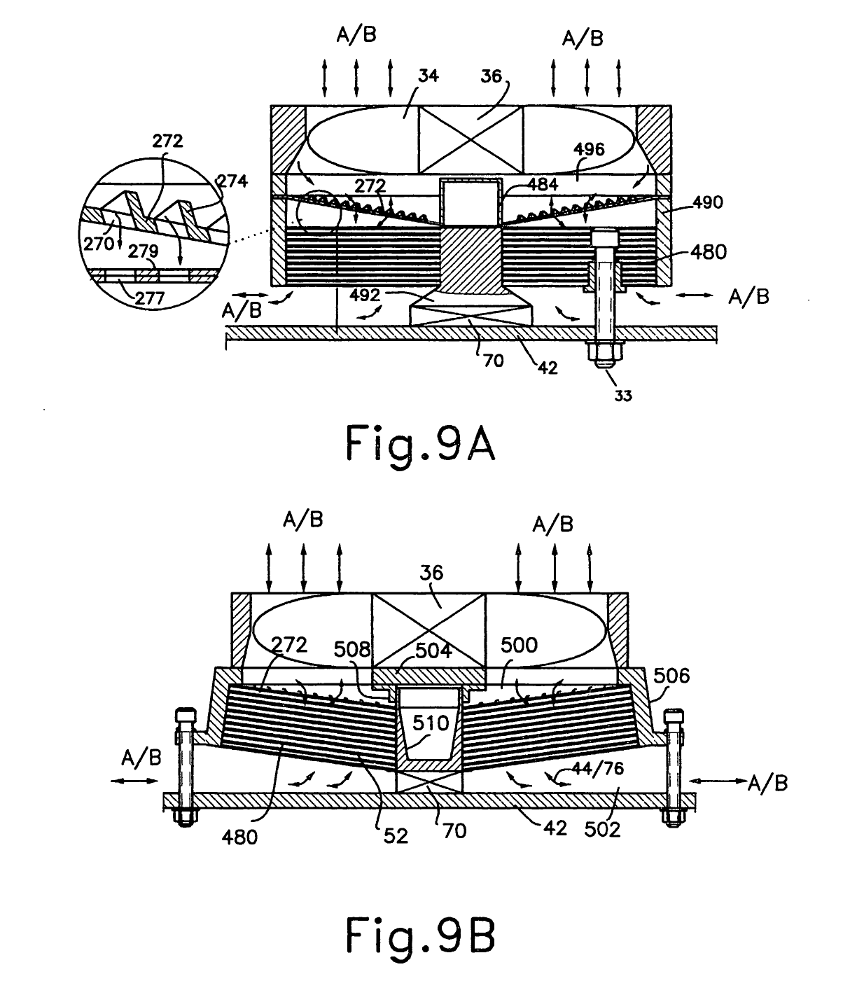

FIGS. 9A and 9B illustrate two configurations of yet another embodiment of the invention.

Referring now to FIG. 9A there is shown a cross-section view of a cooling device composed of perforated stacked plates 480 with plates 480 in metal-to-metal contact or thermally fused into a solid, heat-conducting block which conducts heat through the plates 480 also in the axial direction. A top-mounted axial fan, defined by its motor 36 exhales air (shown by bi-directional arrows A/B) over air-directing plate 272, which is radially-downwardly oblique. Air-directing plate 272 is populated by perforated indentation walls which protrude out of the plate surface in a measure and direction so as to direct the air directly into perforations 277 under plate 272, as described heretofore in reference to FIGS. 4H to 4L, and shown in the magnified detail of FIG. 9A.

The detailed enlargement of air-directing plate 272 in FIG. 9A discloses a preferred shape of the perforations 277 and the protruding walls 274. Air-directing plate 272 is downwardly inclined, with the distance between plate 272 and the heat-sink decreasing toward the center and the height of the protrusions 274 above the surface of plate 272 preferably increasing toward the center. The preferred relation between the air-directing plate 272, the perforations 277, and the flowing air (shown by arrows A/B) is when the protrusions 274 are facing the air exhaled from the fan tangentially and directing the air downwardly at minimal losses directly into the perforations 277 without impinging on the top disposed bars 279.

Bulge 484 in the center of the heat-sink is optionally provided aiming to prevent the formation of a vortex in the center, which consumes pressure energy without donating to the cooling effect. Plenum 496 is optional intending to more-gradually direct the airflow exhaled from the fan. Envelope 490 is supported on the indented fins 480. Core 492 is expanded at the base to overlap exactly the hot surface of heat-generating component 70.

Air-directing plate 272 can be oppositely oblique with the distance between the plate 272 and the heat-sink increasing toward the center. With this type of air-directing plate, the bulge 484 is avoided and the space provided for the air exhaled peripherally from the axial fan, is larger. Air can flow in both directions as indicated by the bi-directional arrows A/B.

As is known to those skilled in the art, increasing the volume of the plenum between the fan plane and the upper side of the heat-sink, in any applicable embodiment, will reduce air velocity and increase air pressure within the plenum leading to reduced pressure losses and, with properly sized perforations, to proper radial distribution of the air within the perforations, to fulfill any operative optimization criteria, as described hereinbefore.

Furthermore, differently inclined air-directing plates, such as for example an upwardly inclined plate, is also applicable as an air-directing means, with the distance between the plate and the fan decreasing toward the center, and the height of the protrusions above the plate surface either being held uniform or changing toward the center so as to ensure the desired air distribution over the differently heated up perforations from the center toward the periphery.

FIG. 9B is a cooling device comprising flow-through, stacked perforated plates 480 mounted on a hollow central solid core 510 with the plates 480 axially bent and oblique in respect to the surface of PCB 42 whereupon the cooling device is mounted. The upper boundary plate 500 is an air-directing plate similar to plate 272 described above, with each perforation in boundary plate 500 overlapping a like perforation in each of the stacked plates 480 beneath, all plates 480 being aligned with each other. The axial cross-section area of the space 502 between the heat-sink and PCB 42 increases in the direction of the periphery allowing for the increased volume of air (shown by arrows A/B) from the perforations to be exhaled. Element 504 is part of the oblique envelope 506 surrounding the bent and oblique plates 480, while hub 508 mechanically connects section 504 to core 510.

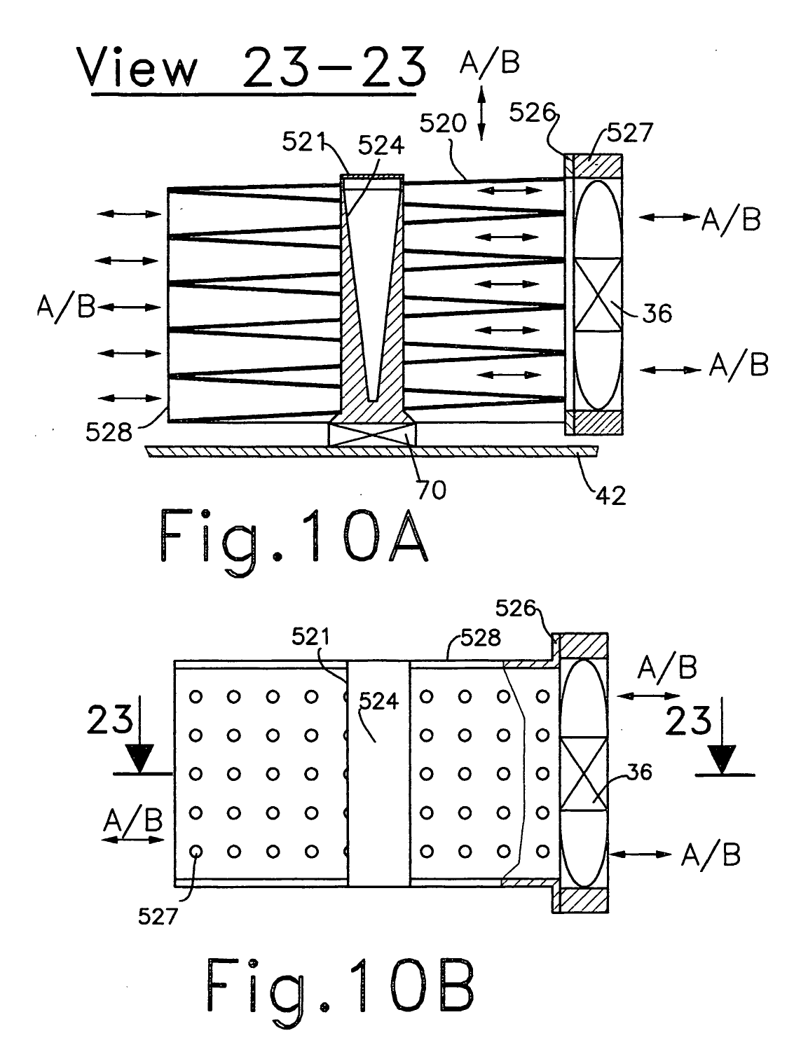

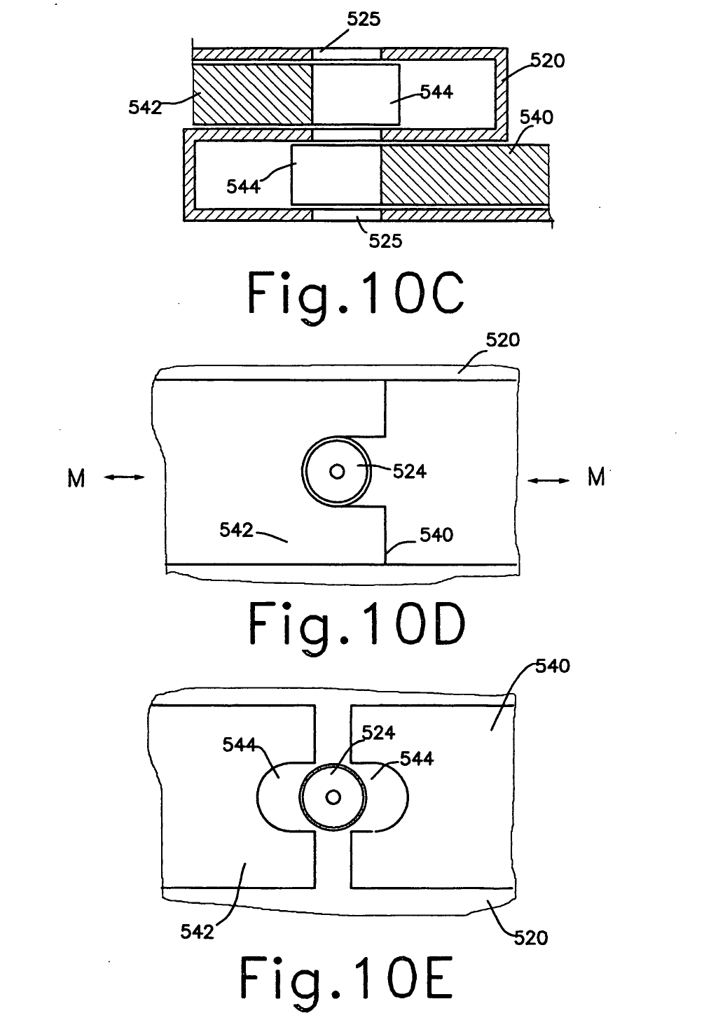

FIGS. 10A and 10B are a cross-section View 23-23 and a top axial cross-section view of yet another embodiment of the invention comprising oblique spaced-apart, continuously folded, perforated strip-fins.

Referring now to FIGS. 10A and 10B in detail, the cooling device in this embodiment of the invention comprises oblique spaced-apart, continuously folded, perforated strip-fins 520 with all the holes 525 overlapping in each section. Fins 520 are thermally attached to a core 524 which is internally-bored to reduce its weight.

A side-mounted fan defined by its motor 36 and walls 527, is mounted on flanges 526 which are an extension of sides cover 528, which covers two sides of the fins 520. Air can be inhaled or exhaled (arrows A/B) into the space between the fins 520 and through the perforations 527, while flowing also parallel to the strip fins 520. By properly sizing and distributing the perforations 527 in respect to the performance curve of the fan 36, any desirable flow regime can be accomplished. The area of the walls of the perforations confined within the plates is preferably larger than twice the foot print area of the perforations in a manner which increases the contact area between the air and the fins as compared to non-perforated plates. Put in another way, the footprint-area of each of the perforations is smaller than half the area of the walls of each of the perforations.

The change in airflow direction when passing through the perforations to some extent disturbs the boundary layer between the air and the fins and increases the heat dissipation on account of increased pressure losses which the fan 36 provides. Section 521 supports the side covers 528 on the core 524.

FIG. 10C is a cross-section view of folded fins or spaced-apart discrete fins cut before mounting on a solid core in accordance with the principles of the invention.

FIGS. 10D and 10E illustrate a preferred method of mounting continuously folded, perforated strip-fins onto a core in accordance with the principles of the invention.

Referring now to FIGS. 10C to 10E in greater detail, there is illustrated a method for mounting the folded plate fins 544 from FIG. 10C in a press-fit attachment on a central core 524 (shown in FIGS. 10D and 10E) while preserving the relative position and distance between the fins 544. A section of a continuously folded strip 520 is shown with a set of thin blades, represented by blades 540 and 542, each comprising a half circle cut-off end 544 inserted as indicated by arrows M into the space between the blades 540/542 at exact fit between the blades 540/542 and the spaced apart fins 544 in a manner which keep the folded fins 544 in exact folded position and support the hole periphery 525 from collapsing or buckling when the core 524 is forcefully press-fitted into the plate fins 544 With the blades 540/542 supporting the circular core 524, plate fins 544, shown in FIGS. 1D and 1E, are press-fit into the space formed by hole periphery 525 provided in the plate fins 544 at a predefined press-fit. Once core 524 is inserted, the blades 540/542 are pulled out.

FIGS. 11A and 11B are a radial cross-section View 24-24 and a top view, respectively, of an embodiment of the invention comprising meshed, woven-metal grid fins.

Referring now to FIGS. 11A and 11B in detail, the cooling device with plate fins 564 in the form of sections of meshed woven-metal grid are shown mounted on a star-shaped base 560 —marked in hidden dotted lines in FIG. 11B—comprising a plurality of protruding pin-cores 562, thermally attached to a woven-wire mesh.

FIG. 11A is a cross-section View 24-24 of FIG. 11B. The enlargements in FIG. 11B display two configurations of pins: one with a circular cross-section, and another, in a preferred embodiment of the invention, with a square cross-section. An axial fan defined by its motor 36 is mounted on the heat-sink. The upper side of the base 560 is oblique to enable airflow also throughout the fins directly above the base 560.

With a woven meshed grid 564, as illustrated in FIG. 11B and in details of the mesh, the air will flow also radially through the radial gaps formed between the bends in the wires intersections in adjacent plates. Accordingly, this embodiment is operatively similar to indented and perforated plates wherein the air flows axially and radially within the finned area.

The pins 562 protruding from the star-shaped base 560 are engaged with all the wires composing the sections and accordingly provide mechanical support to the wires 564 in the axial direction to prevent the network from disintegrating. The pins 562 provide thermal contact with all the wires 564. Using a meshed grid wherein all the wire-junctions are welded, creates thermal and mechanical integrity of the wires, thus a smaller base 560 and number of pins 562 can be employed, as all the wires 564 are mechanically and thermally connected by the welds. Air flows in both directions as indicated by the arrows A/B.

Having described the present invention with regard to certain specific embodiments thereof, it is to be understood that the description is not meant as a limitation, since these embodiments can be constructed with different proportions between the sizes and shapes of the elements composing the heat-sink and the dimensions of the air-moving means. These embodiments can be composed with different relative positions of the air-moving means in respect to each element composing the heat-sink. Air-moving means of different types, sizes, and different operating curves can be adapted to each specific heat-sink to optimize the over-all operation of a cooling device in accordance with any desirable optimization criteria, such as, by way of example, in the preferred embodiments illustrated hereinbefore. Further modifications will now suggest themselves to those skilled in the art, and it is intended to cover such modifications as fall within the scope of the appended claims.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. A heat sink adapted for cooling at least one heat generating component, said heat sink being adapted to operate in association with at least one air moving means so as to generate airflow therethrough and remove the generated heat thereby, said heat sink comprising:
at least one heat conducting element adapted to be in thermal contact with the heat generating component, said one heat conducting element also being in thermal contact with a plurality of fins having through fin-perforations defining free airflow passages therethrough and heat paths therebetween so as to spread the generated heat through said perforated fins, said plurality of perforated fins having a structural configuration and relative spatial disposition so as to form airflow directing means for the generated airflow,
at least one air inlet having associated therewith at least one inflow air passage for inflowing air, and
at least one air outlet having associated therewith at least one outflow air passage for outflowing air, said inflow and outflow air passages being in fluid communication via said fin-perforations,
such that when the air moving means is operative to generate the airflow into said at least one inflow air passage, said airflow directing means at least partially blocks the generated airflow so as to direct substantially all of the generated airflow flowing within said at least one inflow air passage to flow therefrom into said at least one outflow air passage via each of said fin-perforations, thereby developing cross-flow only once through each of said fin-perforations so as to exit via said at least one air outlet.

48. The heat sink of claim 47 wherein at least a portion of said perforated fins are arranged obliquely relative to a respective portion of proximate ones of said perforated fins.

49. The heat sink of claim 48 wherein said perforated fins are arranged oblique to one another in accordion-like fashion, said perforated fins having edges, a portion of said edges being spaced apart, and another portion of said edges being joined, said spaced apart edges defining sides having airflow blocking means disposed at least on a portion thereof, proximate pairs of said joined edges defining therebetween said air outlet on one side of the heat sink and said air inlet on the other side thereof.

50. The heat sink of claim 47 wherein said fin-perforations have associated therewith fin-protrusions, providing additional airflow directing means, said fin-protrusions extending from said perforated fins into at least said inflow air passages so as to direct a portion of the generated airflow toward the associated fin-perforations.

51. The heat sink of claim 47 wherein said perforated fins have edges, at least a portion of said edges being spaced apart, said spaced apart edges defining sides each having a perforated cover disposed thereon, so as to form fluid communication between said at least one inflow and said at least one outflow air passages and the ambient air external to the heat sink, with at least a portion of said cover-perforations having associated therewith cover-protrusions, said cover-protrusions extending into at least a portion of said inflow and outflow air passages so as to force at least a portion of the generated airflow to be exhausted therefrom through a portion of said cover-perforations into the ambient air external to the heat sink, while another portion of said cover-perforations admits ambient air into the heat sink

52. The heat sink of claim 48 wherein said perforated fins are arranged oblique to one another in accordion-like fashion, said perforated fins having edges, a portion of said edges being spaced apart, and another portion of said edges being joined, said spaced apart edges defining sides each having a perforated cover disposed thereon, proximate pairs of said joined edges defining said at least one air outlet and said at least one air inlet therebetween, so as to form fluid communication between said at least one inflow and said at least one outflow air passage and the ambient air external to the heat sink, with at least a portion of said cover-perforations having associated therewith cover-protrusions, said cover-protrusions extending into at least a portion of said inflow and outflow air passages so as to force at least a portion of the generated airflow to be exhausted therefrom through a portion of said cover-perforations into the ambient air external to the heat sink, while another portion of said cover-perforations admits ambient air into the heat sink

53. The heat sink of claim 47 having a symmetrical configuration in which said at least one air inlet and said at least one air outlet are interchangeable in accordance with the flow direction of the generated airflow.

54. The heat sink of claim 47 wherein said plurality of perforated fins are arranged in a stacked fashion, such as to substantially align said at least one inflow air passages and said at least one outflow air passage.

55. The heat sink of claim 54 wherein said substantially aligned at least one inflow air passage is merged with the respective at least one outflow air passage into a continuous air passage.

56. The heat sink of claim 47 wherein said fin-perforations are configured and disposed on the corresponding fins in accordance with at least one of the groups comprising:
a) fin-perforations wherein the cumulative free-airflow area thereof is in a ratio smaller than 30% in respect to the aggregate surface area of the corresponding fin element;
b) fin-perforations wherein the free-airflow area provided by each and every singular fin thereof is smaller than 12 mm²;
c) fin-perforations wherein the cumulative free-airflow area thereof is larger than the area of said corresponding air inlet;
d) fin-perforations wherein the cumulative free-airflow area thereof is larger than the area of said corresponding air outlet;
e) fin-perforations wherein the cumulative free-airflow area thereof on a particular fin is different than the cumulative free-airflow area thereof on an adjacent fin;
f) fin-perforations disposed so as to form non-perforated continuous heat spreading paths each having a radial component;
g) fin-perforations at least a portion thereof having free-airflow area being non-uniformly sized;.
h) fin-perforations at least a portion of the walls thereof being inclined oriented in respect to the surface of the respective fin;
i) fin-perforations at least a portion of the walls thereof being inclined oriented in respect to the direction of said inflowing air;
j) fin-perforations disposed in staggered fashion in respect to adjacent ones thereof at least in the direction of the generated air flow;
k) fin-perforations at least a portion of the walls thereof being non-uniformly oriented in respect to the walls of adjacent fin perforations;
l) fin-perforations at least a portion thereof being non-uniformly shaped; and
m) fin-perforations at least a portion thereof being non-uniformly spaced apart so as to form therebetween non-uniformly sized bars.

57. The heat sink of claim 56 wherein said fin-perforations have associated therewith fin-protrusions being configured and disposed on the corresponding fins in accordance with at least one of the groups comprising:
a) fin-perforations and associated fin-protrusions having at least a portion of the walls and surface thereof inclined oriented in respect to the surface of the respective fin;
b) fin-perforations and associated fin-protrusions having at least a portion of the walls and surface thereof inclined oriented in respect to the generated airflow direction;
c) fin-perforations and associated fin-protrusions at least a portion of the walls and surface thereof defining a continuous surface;
d) fin-perforations wherein at least a portion of the associated fin-protrusions are non-uniformly sized;
e) fin-perforations wherein at least a portion of the associated fin-protrusions are non-uniformly shaped; and
h) fin-perforations wherein at least a portion of the associated fin-protrusions are none uniformly oriented.

58. The heat sink of claim 51 wherein said cover-perforations have associated therewith cover-protrusions being configured and disposed in accordance with at least one of the groups comprising:
a) cover-perforations and associated cover-protrusions being disposed in staggered fashion in the direction of the generated airflow;
b) cover-perforations and associated cover-protrusions having at least a portion of the walls and surface thereof inclined oriented in respect to the surface of the respective covers;
c) cover-perforations and associated cover-protrusions at least a portion of the walls and surface thereof defining a continuous surface;
d) cover-perforations and associated cover-protrusions at least a portion thereof being non-uniformly sized;
e) cover-perforations and associated cover-protrusions at least a portion thereof being non-uniformly shaped;
f) cover-perforations and associated cover-protrusions at least a portion thereof being non-uniformly spaced apart; and
j) cover-perforations and associated cover-protrusions at least a portion thereof being non-uniformly oriented.

59. The heat sink of claim 47 wherein said at least one heat conducting element has a peripheral envelope with said perforated fins surrounding said envelope.

60. The heat sink of claim 47 wherein at least a portion of said perforated fins surface is obliquely disposed in respect to said heat conducting element.

61. The heat sink of claim 47 specifically structured in adaptation to a specific type of air moving means and to a specific relative disposition thereof, so as to characterize the generated airflow in accordance with characteristics selected from at least one of the groups comprising
a) the air exhausted from said at least one air outlet has substantially uniform temperature;
b) the air exhausted from said at least one air outlet has substantially uniform velocity;
c) the air pressure drop across the heat sink is substantially the minimal; and
d) the rate of heat dissipation by the generated airflow is substantially the maximal.

62. The heat sink of claim 49 wherein at least a portion of said perforated fins are provided as folded sections of a folded perforated strip.

63. The heat sink of claim 51 wherein at least a portion of said covers is spaced apart from each of the respective sides with at least a portion of said cover-protrusions extending into the space formed between said covers and said sides.

64. The heat sink of claim 52 wherein at least a portion of said covers is spaced apart from each of the respective sides with at least a portion of said cover-protrusions extending into the space formed between said covers and said sides.

65. The heat sink of claim 49 wherein said airflow blocking means is a cover, at least a portion of the surface of said cover being thermally attached to at least a portion of said fin edges and another portion of said cover surface is adapted to form thermal contact with said heat generating component so as to adapt said cover to function also as the heat conducting element.

66. The heat sink of claim 49 wherein said heat conducting element is configured as a base plate having one side being in thermal contact with a portion of said joined edges, with the oppositely-facing joined edges defining between proximate pairs thereof said at least one air inlet, with said airflow blocking means partially covering said sides so as to define said at least one air outlet through the unblocked portion of said sides.

67. The heat sink of claim 47 wherein the air moving means is connected thereto, the air moving means having its motor connected to a blade-supporting impeller so as to generate said airflow when the motor is activated and to form a self-contained cooling device.

68. The heat sink of claim 67 wherein said motorized air moving means is a radial blower comprising a through-slotted radial impeller, wherein said impeller peripherally supports radial blades so as to externally and radially define between said radial blades a surrounded space in fluid contact with the ambient air at least through said slotted impeller,
said space being adapted to completely house at least said fins so as to direct the generated airflow at least through said slotted impeller into said inflow air passages.

69. The heat sink of claim 68 wherein said heat conducting element is formed with an annular shape provided with an internal hollow section formed therein, said internal hollow section wholly encompassing said motor, with said fins radially protruding from said heat conducting element so as to become wholly disposed within said surrounded space,
wherein said heat conducting element further comprises means so as to reduce the resistance to tangential heat flow there-through.

70. The cooling device of claim 67 wherein said fin-perforations are bordered by bars, said bars having their structure and relative disposition selected from at least one of the groups comprising;
a) bars obliquely oriented in respect to the projection of said blades thereon;
b) bars having a cross section sized as to provide uniform heat flux therethrough; and
c) bars having a heat path direction therethrough containing a radial component.

71. The heat sink of claim 50 wherein said fin-perforations are disposed on said fin protrusions.

72. The heat sink of claim 51 wherein said cover-perforations are disposed on said cover protrusions.

73. The heat sink of claim 47 wherein said perforated-fins are heat conducting sheets selected from at least one of the groups comprising:
a) planar formed sheets;
b) spatial formed sheets;
c) piece-wise planar formed sheets;
d) piece-wise spatial formed sheets; and
e) piece-wise planar and piece-wise spatial formed sheets.

74. The heat sink of claim 73 comprising at least one stack projecting from said at least one heat conducting element.

75. A method for cooling at least one heat generating component, said method comprising:
providing a heat sink being adapted to operate in association with at least one air moving means;
providing at least one heat conducting element adapted to be in thermal contact with the heat generating component, said one heat conducting element also being in thermal contact with a plurality of fins having through fin-perforations defining a free airflow passages therethrough and heat paths therebetween so as to spread the generated heat through said perforated fins, said plurality of perforated fins having a structural configuration and relative spatial disposition;
providing at least one air inlet having associated therewith at least one inflow air passage for inflowing air, and
providing at least one air outlet having associated therewith at least one outflow air passage for out flowing air, said inflow and outflow air passages being in fluid communication via said fin-perforations,
such that when the air moving means is operated, airflow is generated therethrough and the generated heat is removed thereby,
said perforated fins forming airflow directing means for the generated airflow.
